(19) United States
(12) Patent Application Publication
(10) Pub. No.: US 2026/0247806 A1
(43) Pub. Date: Aug. 20, 2026

(54) DISPLAY APPARATUS AND ELECTRONIC DEVICE INCLUDING THE SAME

(71) Applicant: Samsung Display Co., Ltd., Yongin-si (KR)

(72) Inventor: Guanghai Jin, Yongin-si (KR)

(21) Appl. No.: 19/409,189

(22) Filed: Dec. 4, 2025

(30) Foreign Application Priority Data
Feb. 19, 2025 (KR) 10-2025-0021540

(51) Int. Cl. H10K 59/123; H10K 59/122

(52) U.S. Cl. CPC H10K 59/123; H10K 59/122

(57) ABSTRACT

Provided are a display apparatus having an efficient pixel structure, and an electronic device comprising the display apparatus. The display apparatus includes a first sub-pixel group corresponding to a first dot on a screen, and including a first via hole area, a ring type first sub-pixel surrounding the first via hole area in a plan view, a ring type second sub-pixel surrounding the first sub-pixel in a plan view, and a ring type third sub-pixel surrounding the second sub-pixel in a plan view, a second sub-pixel group corresponding to a second dot on the screen, and a third sub-pixel group corresponding to a third dot on the screen.

### CROSS-REFERENCE TO RELATED APPLICATION

The present application claims priority to, and the benefit of, Korean Patent Application No. 10-2025-0021540, filed on Feb. 19, 2025, in the Korean Intellectual Property Office, the entire disclosure of which is incorporated herein by reference.

### BACKGROUND

### 1. Field

One or more embodiments relate to a display apparatus having an efficient pixel structure and an electronic device including the display apparatus.

### 2. Description of the Related Art

A display apparatus may receive information about an image and display the image. The display apparatus may be used as a display portion in small products, such as mobile phones, or as a display portion in large products, such as televisions.

The display apparatus includes a plurality of pixels that emit light by receiving electrical signals to display images externally. Each pixel includes a light-emitting element, and for example, in the case of an organic light-emitting display apparatus, the pixel may include an organic light-emitting diode as the light-emitting element. Generally, the display apparatus may include a thin film transistor and an organic light-emitting diode on a substrate.

Meanwhile, an electronic device may provide, through the display apparatus, a visual interface suitable for a user.

### SUMMARY

One or more embodiments include a display apparatus having an efficient pixel structure and an electronic device including the display apparatus. However, these objectives are merely examples, and the scope of the disclosure is not necessarily limited thereto.

Additional aspects will be set forth in part in the description which follows and, in part, will be apparent from the description, or may be learned by practice of the presented embodiments of the disclosure.

According to one or more embodiments, a display apparatus includes a first sub-pixel group corresponding to a first dot on a screen, and including a first via hole area, a ring type first sub-pixel surrounding the first via hole area in a plan view, a ring type second sub-pixel surrounding the first sub-pixel in a plan view, and a ring type third sub-pixel surrounding the second sub-pixel in a plan view, a second sub-pixel group corresponding to a second dot on the screen, and a third sub-pixel group corresponding to a third dot on the screen.

The first sub-pixel group may further include a second via hole area outside an outer border of the second sub-pixel, and a third via hole area outside an outer border of the third sub-pixel.

The second sub-pixel may have a shape that is indented toward a center by a second area in a plan view, wherein the second via hole area is in the second area, wherein the third sub-pixel has a shape that is indented toward the center by a third area in a plan view, and wherein the third via hole area is in the third area.

A geometric center of the second sub-pixel and a geometric center of the third sub-pixel may be within the first sub-pixel in a plan view.

The first via hole area, the second via hole area, and the third via hole area may overlap a virtual straight line.

A cross section of the first via hole area may include a substrate, a thin film transistor layer above the substrate and including a thin film transistor, a first insulating layer above the thin film transistor layer, a conductive layer above the first insulating layer, a second insulating layer above the conductive layer and defining a through hole exposing an upper surface of the conductive layer, a pixel electrode above the second insulating layer and electrically connected to the conductive layer through the through hole, and a pixel-defining layer above the pixel electrode.

In a plan view, the through hole may be at a center of the first sub-pixel, wherein the pixel electrode has a step difference at the through hole.

The pixel-defining layer may cover the step difference.

The first via hole area, the second via hole area, and the third via hole area may be non-emission areas.

The display apparatus may further include an additional component area surrounded by the first sub-pixel group, the second sub-pixel group, and the third sub-pixel group in a plan view.

The display apparatus may further include an additional sub-pixel in the additional component area.

The display apparatus may further include an additional sub-pixel group in the additional component area.

According to one or more embodiments, a display apparatus includes a first sub-pixel group corresponding to a first dot on a screen and including a first sub-pixel, a ring type second sub-pixel surrounding the first sub-pixel in a plan view, a ring type third sub-pixel surrounding the second sub-pixel in a plan view, and a first via hole area outside an outer border of the first sub-pixel, a second sub-pixel group corresponding to a second dot on the screen, and a third sub-pixel group corresponding to a third dot on the screen.

The first sub-pixel group may further include a second via hole area outside an outer border of the second sub-pixel, and a third via hole area outside an outer border of the third sub-pixel.

The first sub-pixel may have a shape that is indented toward a center by a first area in a plan view, wherein the first via hole area is in the first area.

The second sub-pixel may have a shape that is indented toward the center by a second area in a plan view, wherein the second via hole area is in the second area, and wherein the third sub-pixel has a shape that is indented toward the center by a third area in a plan view, and wherein the third via hole area is in the third area.

In a plan view, the first via hole, the second via hole area, and the third via hole area may overlap a virtual straight line.

In a plan view, the first via hole area may be at a first side of the first sub-pixel, wherein, in a plan view, the second via hole area is at a second side of the second sub-pixel that is opposite to the first side such that a center of the first sub-pixel is between the first via hole area and the second via hole area.

In a plan view, the third via hole area may be at a first side of the third sub-pixel.

According to one or more embodiments, an electronic device includes a memory for storing data information, a processor configured to generate a data signal and/or a control signal based on the data information, and a display apparatus configured to receive the data signal and/or the control signal, and including a first sub-pixel group corresponding to a first dot on a screen, and including a first via hole area, a ring type first sub-pixel surrounding the first via hole area in a plan view, a ring type second sub-pixel surrounding the first sub-pixel in a plan view, and a ring type third sub-pixel surrounding the second sub-pixel in a plan view, a second sub-pixel group corresponding to a second dot on the screen, and a third sub-pixel group corresponding to a third dot on the screen.

### BRIEF DESCRIPTION OF THE DRAWINGS

The above and other aspects of certain embodiments of the disclosure will be more apparent from the following description taken in conjunction with the accompanying drawings, in which:

FIG. 1 is a plan view schematically showing a display panel according to one or more embodiments;

FIG. 2 is a plan view schematically showing a display panel according to one or more embodiments;

FIG. 3 is a schematic cross-sectional view of the display panel taken along the line A-A′ of FIG. 1, according to one or more embodiments;

FIG. 4 is a schematic cross-sectional view of the display panel taken along lines I-I′ and II-II′ of FIG. 1;

FIGS. 5 and 6 are plan views of the display panel, schematically showing a sub-pixel pattern of a first display area of FIG. 1;

FIGS. 7 to 11 are plan views of the display panel, schematically showing a pixel pattern of a portion of a display area of FIG. 1, according to one or more embodiments;

FIG. 12 is an enlarged view of the display panel, showing a first sub-pixel group of FIG. 7, according to one or more embodiments;

FIG. 13 is an enlarged view of the display panel, showing a first sub-pixel group of FIGS. 8 to 11, according to one or more embodiments;

FIG. 14 is a cross-sectional view of the display panel taken along the line B-B′ of FIGS. 12 and 13, according to one or more embodiments;

FIG. 15 is an enlarged view of the display panel, showing a first sub-group pixel of FIG. 7, according to one or more embodiments;

FIG. 16 is an enlarged view of the display panel, showing a first sub-pixel group of FIGS. 8 to 11, according to one or more embodiments;

FIG. 17 is a cross-sectional view of the display panel taken along the line C-C′ of FIGS. 15 and 16, according to one or more embodiments;

FIGS. 18 to 22 are plan views of the display panel, schematically showing a pixel pattern of a portion of a display area of FIG. 1, according to one or more embodiments;

FIGS. 23 to 26 are plan views of the display panel, schematically showing a pixel pattern of a portion of a display area of FIG. 1, according to one or more embodiments;

FIGS. 27 and 28 are plan views of the display panel, schematically showing a pixel pattern of a portion of a display area of FIG. 1, according to one or more embodiments;

FIGS. 29 to 34 are plan views of the display panel, schematically showing a pixel pattern of a portion of a display area of FIG. 1, according to one or more embodiments;

FIGS. 35 to 38 are plan views of the display panel, schematically showing a pixel pattern of a portion of a display area of FIG. 1, according to one or more embodiments;

FIG. 39 is a block diagram of an electronic device according to one or more embodiments; and

FIG. 40 is a schematic diagram of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

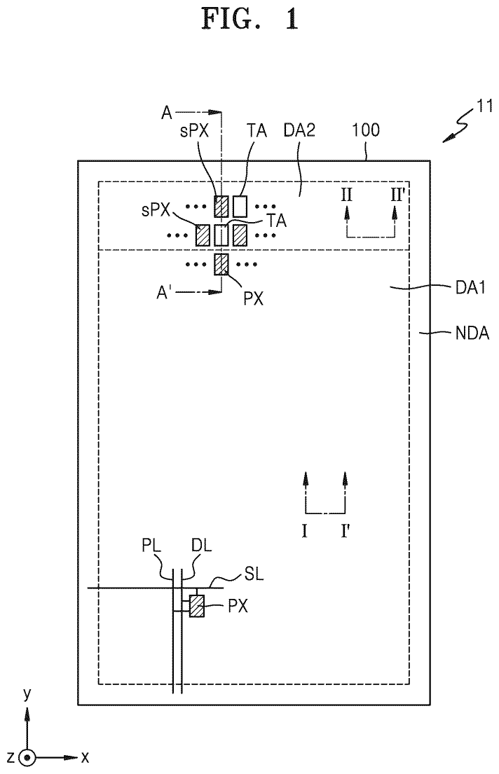

FIG. 1 is a plan view schematically showing a display panel according to one or more embodiments.

Referring to FIG. 1, the display panel may include a first display area DA1 that displays an image and a non-display area NDA that does not display an image. The display panel may provide a main image using light emitted from a plurality of sub-pixels PX located in the first display area DA1.

Each of the plurality of sub-pixels PX may include a display element, such as an organic light-emitting element. Each of the plurality of sub-pixels PX may emit, for example, red, green, or blue light. The sub-pixel PX may be connected to a pixel circuit including a thin film transistor TFT, a storage capacitor, etc. The pixel circuit may be connected to a scan line SL configured to transmit a scan signal, a data line DL intersecting with the scan line SL and configured to transmit a data signal, and a driving voltage line PL configured to supply a driving voltage. For example, the data line DL and the driving voltage line PL may extend in a y-axis direction (hereinafter referred to as a second direction), and the scan line SL may extend in an x-axis direction (hereinafter referred to as a first direction).

The sub-pixel PX may emit light with a brightness corresponding to an electrical signal received from the data line DL. The display area DA may display a certain image through the light emitted from the sub-pixel PX. For reference, the sub-pixel PX may be defined as an emission area emitting any one of red light, green light, and blue light.

The display panel may include a second display area DA2. The second display area DA2 may be an area where components, such as sensors using infrared light, visible light, or sound are located at a lower portion of the display panel, as will be described below. The second display area DA2 may include a transmission portion TA through which light and/or sound output from the component to the outside or traveling from the outside toward the component may pass. In one or more embodiments, when light passes through the second display area DA2, the light transmittance may be about 30% or more, about 50% or more, about 75% or more, about 80% or more, about 85% or more, or about 90% or more.

In one or more embodiments, a plurality of auxiliary sub-pixels sPX may be located in the second display area DA2, and a certain image may be provided using light emitted from the plurality of auxiliary sub-pixels sPX. The image provided in the second display area DA2 may be an auxiliary image, which may have a lower resolution than the image provided in the first display area DA1. That is, because the second display area DA2 includes the transmission portion TA through which light and/or sound may pass, the number of auxiliary sub-pixels sPX located per unit area in the second display area DA2 may be less than the number of sub-pixels PX located per unit area in the first display area DA1.

The second display area DA2 may be located on a side of the first display area DA1, and FIG. 1 shows that the second display area DA2 is located on the upper side of the first display area DA1 and between the non-display area NDA and the first display area DA1. However, the disclosure is not necessarily limited thereto. Various modifications are possible, and for example, the second display area DA2 may be located surrounded by the first display area DA1.

Hereinafter, an organic light-emitting display panel will be described as a display panel according to one or more embodiments, but the display panel of the disclosure is not necessarily limited thereto. In one or more embodiments, various types of the display panel, such as an inorganic light-emitting display panel, a quantum dot light-emitting display panel, etc. may be used.

FIG. 1 shows the second display area DA2 located on the upper side of first display area DA1 which has a rectangular shape, but the disclosure is not necessarily limited thereto. For example, the shape of the first display area DA1 may be circular, elliptical, or polygonal, such as triangular or pentagonal. For example, the second display area DA2 may be located inside the first display area DA1 and may be provided having various shapes.

The non-display area NDA is an area in which a sub-pixel PX and an auxiliary sub-pixel sPX are not located, and may be an area that does not display an image. A power supply line for driving the sub-pixel PX and the auxiliary sub-pixel sPX may be located in the non-display area NDA. Also, pads may be located in the non-display area NDA, and a printed circuit board including a driving circuit unit or an integrated circuit (IC) device, such as a driver IC may be electrically connected to the pads in the non-display area NDA.

For example, the non-display area NDA may be located outside the first display area DA1 and the second display area DA2, and the non-display area NDA may surround the first display area DA1 and the second display area DA2.

For reference, because the display panel 10 includes a substrate 100, it may also be considered that the substrate 100 may include the first display area DA1, the second display area DA2, and the non-display area NDA. The substrate 100 will be described below in detail.

Also, a plurality of transistors may be located in the first display area DA1 and the second display area DA2. Regarding the plurality of transistors, depending on the type (N type or P type) and/or the operation condition of the transistor, a first terminal of the transistor may be a source electrode or a drain electrode, and a second terminal of the transistor may be an electrode different from the electrode of the first terminal among the source electrode and the drain electrode. For example, when the first terminal is a source electrode, the second terminal may be a drain electrode.

For convenience of explanation, each of the sub-pixel PX, the auxiliary sub-pixel sPX, and the transmission portion TA in FIG. 1 is shown having a rectangular shape, but the shape of each of the auxiliary sub-pixel sPX and transmission portion TA is not necessarily limited thereto and may be variously modified. Also, each of the sub-pixel PX, the auxiliary sub-pixel sPX, and the transmission portion TA in FIG. 1 is located in parallel, but the arrangement of each of the sub-pixel PX, the auxiliary sub-pixel sPX, and the transmission portion TA is not necessarily limited thereto, and each arrangement may be variously modified.

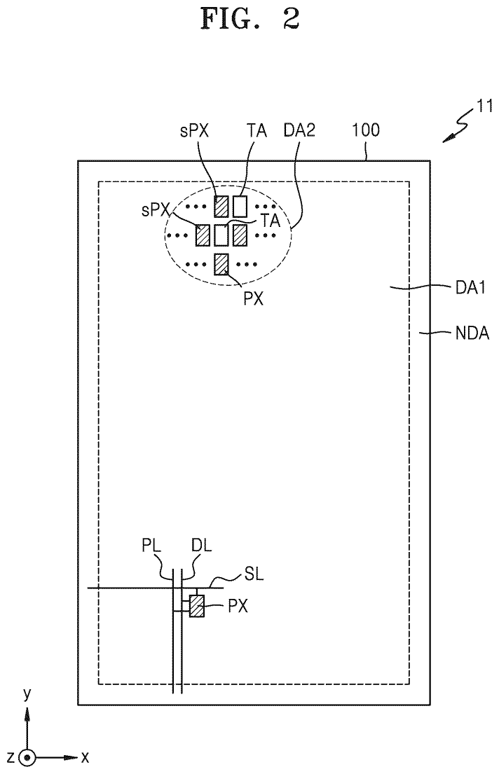

FIG. 2 is a plan view schematically showing a display panel according to one or more embodiments. For reference, descriptions relating to FIG. 2 that are identical to or duplicate those of FIG. 1 may be omitted.

FIG. 1 shows the second display area DA2 located on a side of first display area DA1, but the disclosure is not necessarily limited thereto. For example, as shown in FIG. 2, the second display area DA2 may be provided as an area corresponding to sensors and the like located at a lower portion of the display panel. In this case, the second display area DA2 may be located inside the first display area DA1 and may be surrounded by the first display area DA1.

For convenience of explanation, each of the sub-pixel PX, the auxiliary sub-pixel sPX, and the transmission portion TA in FIG. 2 is shown having a rectangular shape, but the shape of each of the auxiliary sub-pixel sPX and transmission portion TA is not necessarily limited thereto and may be variously modified. Also, each of the auxiliary sub-pixel sPX and the transmission portion TA in FIG. 2 is located in parallel, but the arrangement of each of the auxiliary sub-pixel sPX and the transmission portion TA is not necessarily limited thereto, and each arrangement may be variously modified.

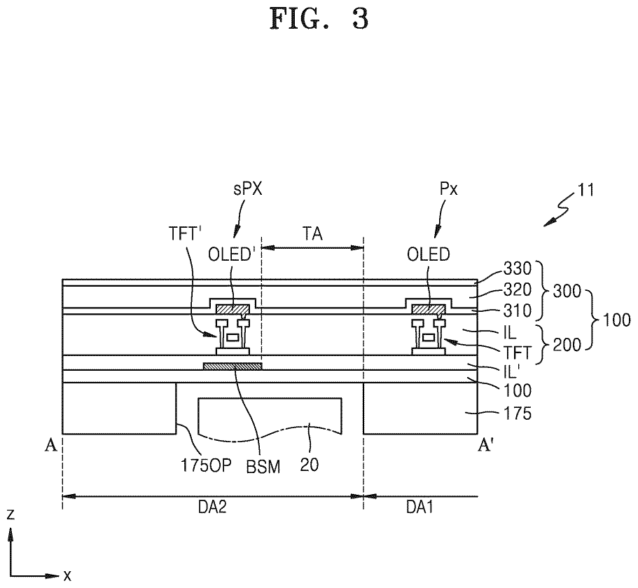

FIG. 3 is a schematic cross-sectional view of the display panel taken along the line A-A′ of FIG. 1, according to one or more embodiments.

For reference, the schematic cross-sectional view along the line A-A′ of FIG. 1 shows a cross-section of one sub-pixel PX, one transmission portion TA, and one auxiliary sub-pixel sPX, and for convenience of explanation, it may be a schematic cross-sectional view obtained based on the boundary between the first display area DA1 and the second display area DA2. Therefore, the schematic cross-sectional view of FIG. 3 may also be understood as a schematic cross-sectional view obtained based on the boundary between the first display area DA1 and the second display area DA2 in FIG. 2.

As shown in FIG. 3, a component 20 corresponding to the second display area DA2 may be located below the display panel 10.

The display panel 10 may include a substrate 100, a display element layer 200 located on the substrate 100, and a thin film encapsulation layer 300 as a sealing member for sealing the display element layer 200. Additionally, the display panel 10 may further include a lower protective film 175 located on the lower portion of the substrate 100.

The substrate 100 may include glass or polymer resin. Also, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including the polymer resin may have flexible, rollable, or bendable characteristics. The substrate 100 may have a multilayer structure including a layer including the aforementioned polymer resin and an inorganic layer, in one or more embodiments.

The display element layer 200 may include a circuit layer including thin film transistors TFT and TFT′, an organic light-emitting diode OLED as a display element, and an inorganic insulating layer IL between the circuit layer and an organic light-emitting diode OLED.

A main sub-pixel Pm including a first thin film transistor TFT and an organic light-emitting diode OLED connected to the first thin film transistor TFT may be located in the first display area DA1, and an auxiliary sub-pixel Pa including a second thin film transistor TFT′ and an organic light-emitting diode OLED connected to the second thin film transistor TFT′ may be located in the second display area DA2.

Additionally, a transmission portion TA in which the display element is not located may be located in the second display area DA2. The transmission portion TA may be understood as an area where light/signals emitted from the component 20 or light/signals incident on the component 20 are transmitted.

The component 20 may be located in the second display area DA2. The component 20 may be an electronic element that uses light or sound. For example, the component 20 may be a sensor that receives and uses light, such as an infrared sensor, a sensor that outputs and detects light or sound to measure distance or recognize fingerprints, a small lamp/light that outputs light, a speaker that outputs sound, a camera, etc. For the electronic element that uses light, it is understood that light of various wavelength bands, such as visible light, infrared light, ultraviolet light, etc. may be used. In one or more embodiments, a plurality of components 20 may be located in the second display area DA2. For example, a light-emitting element and a light-receiving element may be provided together in one second display area DA2 as the components 20. Alternatively, a light-emitting portion and a light-receiving portion may be simultaneously provided in one component 20.

A bottom electrode layer BSM may be located in the second display area DA2. The bottom electrode layer BSM may correspond to the second thin film transistor TFT′ below the second thin film transistor TFT′. The bottom electrode layer BSM may block external light from reaching the auxiliary sub-pixel Pa including the second thin film transistor TFT′. For example, the bottom electrode layer BSM may block light emitted from the component 20 from reaching the auxiliary sub-pixel Pa.

In some embodiments, a constant voltage or signal is applied to the bottom electrode layer BSM, and the bottom electrode layer BSM with the constant voltage or signal applied may reduce or prevent damage to the pixel circuit due to electrostatic discharge.

The thin film encapsulation layer 300 may include at least one inorganic encapsulation layer and at least one organic encapsulation layer. For example, the thin film encapsulation layer 300 includes first and second inorganic encapsulation layers 310 and 330 and an organic encapsulation layer 320 between the first inorganic encapsulation layer 310 and the second inorganic encapsulation layer 330.

The first and second inorganic encapsulation layers 310 and 330 may include one or more inorganic insulating materials, such as aluminum oxide, titanium oxide, tantalum oxide, hafnium oxide, zinc oxide, silicon oxide, silicon nitride, or silicon oxynitride. The organic encapsulation layer 320 may include a polymer-based material. The polymer-based material may include acrylic resin, epoxy resin, polyimide, polyethylene, etc.

The lower protective film 175 may be attached to the lower portion of the substrate 100 to support and protect the substrate 100. The lower protective film 175 may include an opening 175OP corresponding to the second display area DA2. By providing the opening 175OP in the lower protective film 175, the light transmittance of the second display area DA2 may be improved. The lower protective film 175 may include polyethylene terephthalate (PET) or polyimide (PI).

The size of the second display area DA2 may be larger than the size of the area occupied by the component 20. Accordingly, the size of the opening 175OP in the lower protective film 175 may not match the size of the second display area DA2. For example, the size of the opening 175OP may be smaller than the size of the second display area DA2.

Alternatively, a plurality of components 20 may be located in the second display area DA2. The plurality of components 20 may have different functions from each other. For example, one of the plurality of components 20 may be a camera, and another may be an infrared sensor.

In one or more embodiments, elements, such as an input sensing member for sensing a touch input, an anti-reflection member including a polarizer and a retarder or a color filter and a black matrix, and a transparent window may be further located on the display panel 10.

Although the thin film encapsulation layer 300 is shown as an encapsulation member for sealing the display element layer 200, the disclosure is not necessarily limited thereto. For example, a sealing substrate that is bonded to the substrate 100 by a sealant or frit may be used as a member for sealing the display element layer 200.

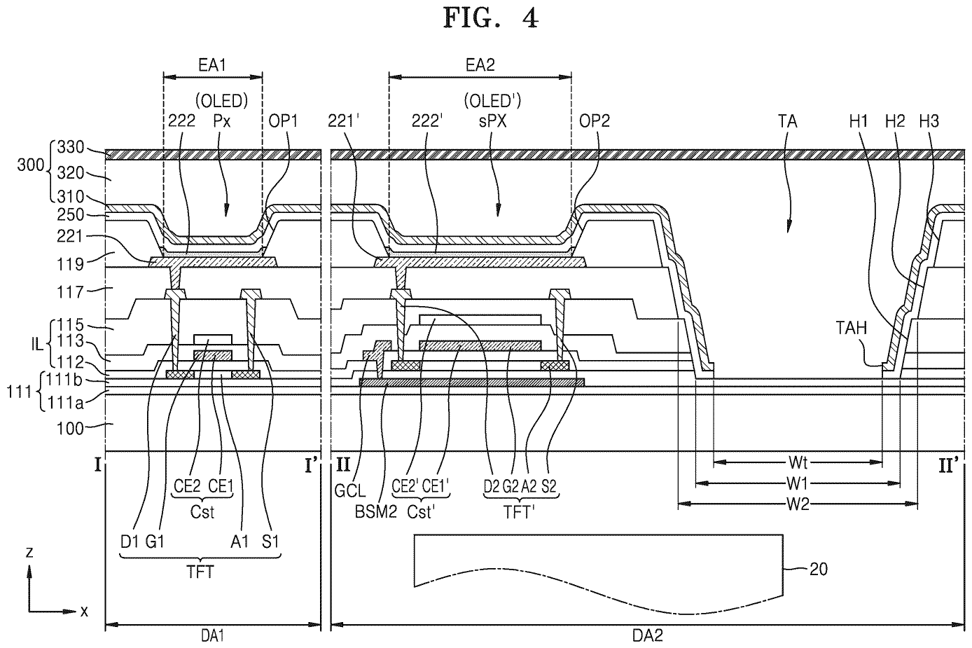

FIG. 4 is a schematic cross-sectional view of the display panel taken along lines I-I′ and II-II′ of FIG. 1.

For reference, at the level of one of ordinary skill in the art, the schematic cross-sectional view along the line I-I′ of FIG. 1 shown in FIG. 4 may be understood as a schematic cross-sectional view obtained from the first display area DA1 of FIG. 2, and the schematic cross-sectional view along the line II-II′ of FIG. 1 shown in FIG. 4 may be understood as a schematic cross-sectional view obtained from the second display area DA2 of FIG. 2.

As shown in FIG. 4, the sub-pixel PX is located in the first display area DA1, and the auxiliary sub-pixel sPX and the transmission portion TA may be located in the second display area DA2.

For example, the sub-pixel PX may include the first thin film transistor TFT, a main storage capacitor Cst, and a main organic light-emitting diode OLED. The auxiliary sub-pixel sPX may include the second thin film transistor TFT′, an auxiliary storage capacitor Cst′, and an auxiliary organic light-emitting diode OLED′. The transmission portion TA may include an opening portion TAH corresponding to the transmission portion TA.

The component 20 may be located under the second display area DA2. The component 20 may be a camera for capturing images or an infrared (IR) sensor for transmitting/receiving infrared light. Because the transmission portion TA is located in the second display area DA2, light transmitted/received from the component 20 may be transmitted. For example, light emitted from the component 20 may travel along the z-direction through the transmission portion TA, and light generated outside the display apparatus and incident on the component 20 may travel along the-z direction through the transmission portion TA. In some embodiments, the component 20 may include a plurality of image sensors, and one image sensor may be located corresponding to one transmission portion TA.

Hereinafter, a stacked structure of layers included in the display apparatus according to one or more embodiments will be described.

The substrate 100 may include glass, metal, or polymer resin. Also, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may have various modifications. For example, the substrate 100 may have a multilayer structure including two layers each including the polymer resin, and a barrier layer including an inorganic material (silicon oxide, silicon nitride, silicon oxynitride, etc.) between the two layers.

A buffer layer 111 is located on the substrate 100 to reduce or block the penetration of foreign substances, moisture, or external air from the lower portion of the substrate 100, and may provide a flat surface on the substrate 100. The buffer layer 111 may include an inorganic material, such as oxide or nitride, an organic material, or a combination of an organic material and an inorganic material, and may have a single or multi-layer structure including an inorganic material and an organic material. In one or more embodiments, a barrier layer for reducing or preventing penetration of external air may be further provided between the substrate 100 and the buffer layer 111. In some embodiments, the buffer layer 111 may include silicon oxide (SiO₂) or silicon nitride (SiNₓ). For example, a first buffer layer 111a and a second buffer layer 111b of the buffer layer 111 may be stacked.

The bottom electrode layer BSM may be located between the first buffer layer 111a and the second buffer layer 111b, in the second display area DA2. In one or more embodiments, the bottom electrode layer BSM may be located between the substrate 100 and the first buffer layer 111a. The bottom electrode layer BSM may be located under the second thin film transistor TFT′, to reduce or prevent degradation of characteristics of the second thin film transistor TFT′ due to light emitted from the component 20, etc.

Also, the bottom electrode layer BSM may be connected through a contact hole to a wiring GCL located on another layer. The bottom electrode layer BSM may receive a constant voltage or a signal from the wiring GCL. For example, the bottom electrode layer BSM may receive a driving voltage ELVDD or a scan signal. As the bottom electrode layer BSM receives a constant voltage or a signal, the risk of electrostatic discharge may be significantly reduced. The bottom electrode layer BSM may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The bottom electrode layer BSM may have a single or multi-layer structure formed of the above material.

The first thin film transistor TFT and the second thin film transistor TFT′ may be located on the buffer layer 111. The first thin film transistor TFT includes a first semiconductor layer A1, a first gate electrode G1, a first source electrode S1, and a first drain electrode D1, and the second thin film transistor TFT′ includes a second semiconductor layer A2, a second gate electrode G2, a second source electrode S2, and a second drain electrode D2. The first thin film transistor TFT may be connected to the main organic light-emitting diode OLED of the first display area DA1 and may drive the main organic light-emitting diode OLED. The second thin film transistor TFT′ may be connected to an auxiliary organic light-emitting diode OLED′ of the second display area DA2 and may drive the auxiliary organic light-emitting diode OLED′.

The first semiconductor layer A1 and the second semiconductor layer A2 may be located on the buffer layer 111, and may each include polysilicon. In one or more embodiments, each of the first semiconductor layer A1 and the second semiconductor layer A2 may include amorphous silicon. In one or more embodiments, each of the first semiconductor layer A1 and the second semiconductor layer A2 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and/or zinc (Zn). Each of the first semiconductor layer A1 and the second semiconductor layer A2 may include a channel region, and a source region and a drain region doped with impurities.

A first gate-insulating layer 112 may be provided to cover the first semiconductor layer A1 and the second semiconductor layer A2. The first gate-insulating layer 112 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate-insulating layer 112 may have a single or multi-layer structure including the above inorganic insulating material.

The first gate electrode G1 and the second gate electrode G2 are located on the first gate-insulating layer 112 to respectively overlap the first semiconductor layer A1 and the second semiconductor layer A2. Each of the first gate electrode G1 and the second gate electrode G2 may have a single or multi-layer structure including molybdenum (Mo), aluminum (Al), copper (Cu), or titanium (Ti). For example, each of the first gate electrode G1 and the second gate electrode G2 may have a single-layer structure including Mo.

A second gate-insulating layer 113 may be provided to cover the first gate electrode G1 and the second gate electrode G2. The second gate-insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The second gate-insulating layer 113 may have a single or multi-layer structure including the above inorganic insulating material.

A first upper electrode CE2 of a main storage capacitor Cst and a second upper electrode CE2′ of an auxiliary storage capacitor Cst′ may be located on the second gate-insulating layer 113.

The first upper electrode CE2 may overlap the first gate electrode G1 located under the first upper electrode CE2, in the first display area DA1. The first gate electrode G1 and the first upper electrode CE2 overlapping each other with the second gate-insulating layer 113 therebetween may constitute the main storage capacitor Cst. The first gate electrode G1 may be a first lower electrode CE1 of the main storage capacitor Cst.

The second upper electrode CE2′ may overlap the second gate electrode G2 located under the second upper electrode CE2′, in the second display area DA2. The second gate electrode G2 and the second upper electrode CE2′ overlapping each other with the second gate-insulating layer 113 therebetween may constitute the auxiliary storage capacitor Cst′. The first gate electrode G1 may be a second lower electrode CE1′ of the auxiliary storage capacitor Cst′.

Each of the first upper electrode CE2 and the second upper electrode CE2′ may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single or multi-layer structure including the above material.

An interlayer insulating layer 115 may be formed to cover the first upper electrode CE2 and the second upper electrode CE2′. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

When the first gate-insulating layer 112, the second gate-insulating layer 113, and the interlayer insulating layer 115 are collectively referred to as an inorganic insulating layer IL, a stacked structure of the inorganic insulating layer IL on the substrate 100 may have a transmittance of about 90% or more with respect to an infrared wavelength. For example, light having a wavelength ranging from about 900 nm to about 1100 nm passing through the substrate 100 and the inorganic insulating layer IL may have a transmittance of about 90%.

The first and second source electrodes S1 and S2 and the first and second drain electrodes D1 and D2 are located on the interlayer insulating layer 115. Each of the first and second source electrodes S1 and S2 and the first and second drain electrodes D1 and D2 may include a conductive material including molybdenum (Mo), aluminum (Al), copper (Cu), or titanium (Ti), and may have a single or multi-layer structure including the conductive material. For example, each of the first and second source electrodes S1 and S2 and the first and second drain electrodes D1 and D2 may have a multi-layer structure including Ti/Al/Ti.

A planarization layer 117 may cover the first and second source electrodes S1 and S2 and the first and second drain electrodes D1 and D2. The planarization layer 117 may have a flat top surface so that a first pixel electrode 221 and a second pixel electrode 221′ located over the planarization layer 117 are flat.

The planarization layer 117 may have a single or multi-layer structure formed of an organic material. The planarization layer 117 may include benzocyclobutene (BCB), polyimide, hexamethyldisiloxane (HMDSO), a general-purpose polymer, such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

An opening portion through which any one of the first source electrode S1 and the first drain electrode D1 of the first thin film transistor TFT is exposed may be formed in the planarization layer 117, and the first pixel electrode 221 may contact the first source electrode S1 or the first drain electrode D1 through the opening portion and may be electrically connected to the first thin film transistor TFT.

Also, an opening portion through which any one of the second source electrode S2 and the second drain electrode D2 of the second thin film transistor TFT′ is exposed may be formed in the planarization layer 117, and the second pixel electrode 221′ may contact the second source electrode S2 or the second drain electrode D2 through the opening portion and may be electrically connected to the second thin film transistor TFT′.

Each of the first pixel electrode 221 and the second pixel electrode 221′ may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more embodiments, each of the first pixel electrode 221 and the second pixel electrode 221′ may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In one or more embodiments, each of the first pixel electrode 221 and the second pixel electrode 221′ may further include a film formed of ITO, IZO, ZnO, or In₂O₃ over/under the reflective film. In some embodiments, each of the first pixel electrode 221 and the second pixel electrode 221′ may have a stacked structure including ITO/Ag/ITO.

A pixel-defining layer 119 may cover an edge of each of the first pixel electrode 221 and the second pixel electrode 221′. The pixel-defining layer 119 overlaps each of the first pixel electrode 221 and the second pixel electrode 221′ and has a first opening OP1 and a second opening OP2 defining an emission area of a sub-pixel. The pixel-defining layer 119 may reduce or prevent the likelihood of an arc or the like occurring on the edge of each of the first and second pixel electrodes 221 and 221′ by increasing a distance between the edge of each of the first and second pixel electrodes 221 and 221′ and a counter electrode 250 located over the first and second pixel electrodes 221 and 221′. The pixel-defining layer 119 may be formed of an organic insulating material, such as polyimide, polyamide, acrylic resin, benzocyclobutene, hexamethyldisiloxane (HMDSO), or phenolic resin by using spin coating or the like.

When the planarization layer 117 and the pixel-defining layer 119 are referred to as an organic insulating layer OL, the organic insulating layer OL may have a transmittance of about 90% or more with respect to an infrared wavelength. For example, light having a wavelength from about 900 nm to about 1100 nm passing through the organic insulating layer OL may have a transmittance of about 90%.

A first intermediate layer 222 and a second intermediate layer 222′ may be located in the first opening OP1 and the second opening OP2 of the pixel-defining layer 119 to respectively correspond to the first pixel electrode 221 and the second pixel electrode 221′. Each of the first intermediate layer 222 and the second intermediate layer 222′ may include a high molecular weight material or a low molecular weight material, and may emit red light, green light, blue light, or white light.

The counter electrode 250 is located over a second functional layer 222c. The counter electrode 250 may include a conductive material having a low work function. For example, the counter electrode 250 may include a semi-transparent layer including silver (Ag), magnesium (Mg), aluminum (Al) platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 250 may further include a layer formed of ITO, IZO, ZnO, or In₂O₃ on the semi-transparent layer including the above material. The counter electrode 250 may be integrally formed to correspond to the sub-pixels PX and the auxiliary sub-pixels sPX included in the first display area DA1 and the second display area DA2.

Layers from the first pixel electrode 221 to the counter electrode 250 formed in the first display area DA1 may constitute the main organic light-emitting diode OLED. Layers from the second pixel electrode 221′ to the counter electrode 250 formed in the second display area DA2 may constitute the auxiliary organic light-emitting diode OLED′.

The counter electrode 250 may include an opening portion TAH corresponding to the transmission portion TA. The opening portion TAH of the counter electrode 250 may be formed by using a laser.

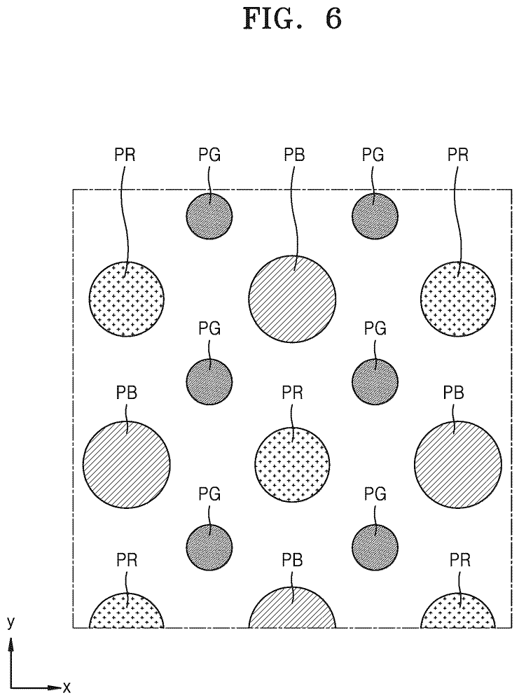

When the opening portion TAH corresponds to the transmission portion TA, it may mean that the opening portion TAH overlaps the transmission portion TA. In this case, the size of the opening portion TAH may be less than the size of a first hole H1 formed in the inorganic insulating layer IL. To this end, in FIG. 6, a width Wt of the opening portion TAH is less than a width W1 of the first hole H1. The size of the opening portion TAH and the size of the first hole H1 may be defined as the size of a narrowest opening.

In some embodiments, the counter electrode 250 may be located at side surfaces of the first hole H1, a second hole H2, and a third hole H3. In some embodiments, gradients of the side surfaces of the first hole H1, the second hole H2, and the third hole H3 with respect to a top surface of the substrate 100 may be less than a gradient of a side surface of the opening portion TAH with respect to the top surface of the substrate 100.

When the opening portion TAH is formed, it means that a member, such as the counter electrode 250 is removed from the transmission portion TA, and thus, a light transmittance of the transmission portion TA may be significantly increased.

The main organic light-emitting diode OLED and the auxiliary organic light-emitting diode OLED′ may be sealed by the thin film encapsulation layer 300. The thin film encapsulation layer 300 may be located on the counter electrode 250. The thin film encapsulation layer 300 may reduce or prevent penetration of external moisture or a foreign material into the main organic light-emitting diode OLED and the auxiliary organic light-emitting diode OLED′.

The thin film encapsulation layer 300 may include at least one inorganic encapsulation layer and at least one organic encapsulation layer, and the thin film encapsulation layer 300 may include the first inorganic encapsulation layer 310, the organic encapsulation layer 320, and the second inorganic encapsulation layer 330. In one or more embodiments, the number of organic encapsulation layers, the number of inorganic encapsulation layers, and an order in which organic encapsulation layers and inorganic encapsulation layers are stacked may be modified.

Each of the first and second inorganic encapsulation layers 310 and 330 may include at least one inorganic insulating material, such as aluminum oxide, titanium oxide, tantalum oxide, hafnium oxide, zinc oxide, silicon oxide, silicon nitride, and/or silicon oxynitride, and may be formed by using chemical vapor deposition (CVD) or the like. The organic encapsulation layer 320 may include a polymer-based material. The polymer-based material may include silicone resin, acrylic resin, epoxy resin, polyimide, and polyethylene.

The first inorganic encapsulation layer 310, the organic encapsulation layer 320, and the second inorganic encapsulation layer 330 may be integrally formed to cover the display area DA and a sensor area SA. Accordingly, the first inorganic encapsulation layer 310, the organic encapsulation layer 320, and the second inorganic encapsulation layer 330 may be located in the opening portion TAH.

For example, the organic encapsulation layer 320 may be integrally formed to cover the first display area DA1 and the second display area DA2, and may not be located in the transmission portion TA. In other words, the organic encapsulation layer 320 may have an opening corresponding to the transmission portion TA. In this case, the first inorganic encapsulation layer 310 and the second inorganic encapsulation layer 330 may contact each other in the opening portion TAH.

For example, the size of the second opening OP2 defining the emission area EA2 of the auxiliary sub-pixel sPX may be larger than the size of the first opening OP1 defining the emission area EA1 of the sub-pixel PX. Accordingly, when receiving the same current, the brightness of the auxiliary sub-pixel sPX may be implemented larger or brighter.

Because the number of auxiliary sub-pixels sPX per unit area in the second display area DA2 is smaller than the number of auxiliary sub-pixels sPX per unit area in the first display area DA1, the brightness implemented per unit area in the first display area DA1 and the brightness implemented per unit area in the second display area DA2 may be implemented to be the same.

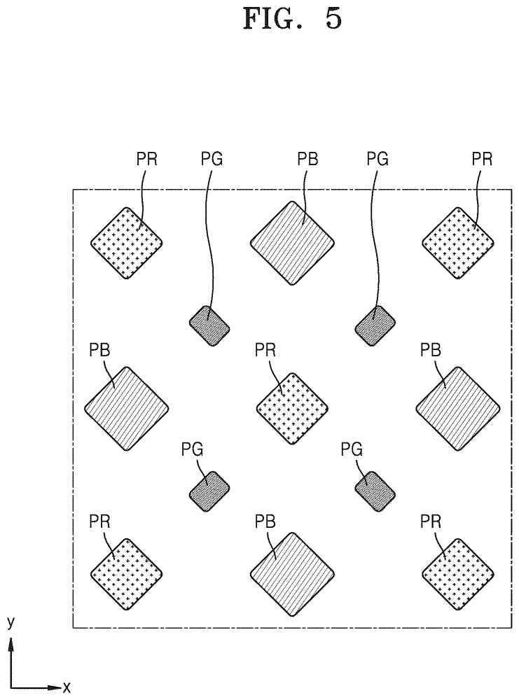

FIGS. 5 and 6 are plan views of the display panel, schematically showing a sub-pixel pattern of a first display area of FIG. 1.

The sub-pixel patterns in FIGS. 5 and 6 are merely examples, and various modified sub-pixel patterns may be formed in the first display area DA1 of FIG. 1.

For example, the sub-pixels of the first display area DA1 may include sub-pixels PB that emit a first wavelength band (for example, a wavelength band in the blue area of visible light), sub-pixels PG that emit a second wavelength band (for example, a wavelength band in the green area of visible light), and sub-pixels PR that emit a third wavelength band (for example, a wavelength band in the red area of visible light).

For example, the shape of the sub-pixels PB, PG, PR in FIG. 5 may be approximately rectangular, and corners thereof may be rounded. For example, the shape of the sub-pixels PB, PG, PR in FIG. 6 may be approximately circular.

For example, the size of each of the sub-pixels PB, PG, PR in FIGS. 5 and 6 may be different. The size of the sub-pixel PB of the first wavelength band may be the largest, and the size of the sub-pixel PG of the second wavelength band may be the smallest. The size of the sub-pixel PR of the third wavelength band may be smaller than the size of the sub-pixel PB of the first wavelength band, and may be larger than the size of the sub-pixel PG of the second wavelength band.

Hereinafter, in the disclosure, “sharing” a corresponding element may mean that two or more elements commonly include the corresponding element. Also, that two or more dots or pixel groups “share” a corresponding sub-pixel may mean that the corresponding sub-pixel is involved in the driving of all of the two or more dots or pixel groups.

A plurality of auxiliary sub-pixels may be grouped into a pixel group, and the pixel group may be a unit element driven as one dot on the screen. For example, when one dot is turned on on the screen, it may mean that auxiliary sub-pixels defined as one pixel group corresponding to the turned-on dot (or at least one of the auxiliary sub-pixels defined as one pixel group) are turned on.

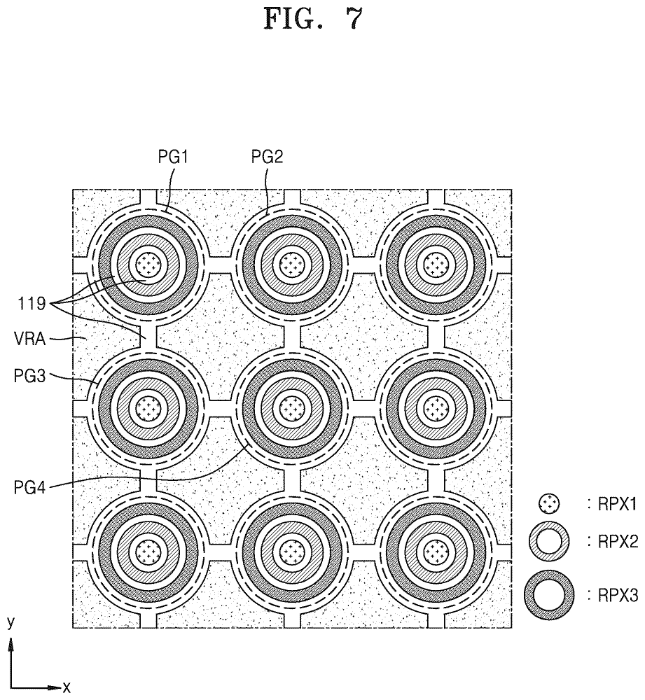

FIGS. 7 to 11 are plan views of the display panel, schematically showing a pixel pattern of a portion of a display area of FIG. 1, according to one or more embodiments. For reference, descriptions of FIGS. 7 to 11 that are the same as or overlap with the above descriptions of FIGS. 1 to 6 may be omitted for conciseness.

For reference, the pixel pattern of FIG. 7 may be a pattern of sub-pixels in the first display area of FIG. 1 or a pattern of auxiliary sub-pixels in the second display area of FIG. 1. For convenience of explanation, the description focuses on the sub-pixel, but when the additional component area is the transmission portion mentioned above, the sub-pixel described in FIG. 7 may be understood as the auxiliary sub-pixel mentioned above.

The display apparatus mentioned in the disclosure may include a plurality of sub-pixels for implementing a screen. The plurality of sub-pixels may include a first sub-pixel RPX1 that generates visible light of a first wavelength band (for example, green visible light), a second sub-pixel RPX2 that generates visible light of a second wavelength band (for example, red visible light), and a third sub-pixel RPX3 that generates visible light of a third wavelength band (for example, blue visible light).

The plurality of sub-pixels may be classified into a plurality of sub-pixel groups. To implement an image, a plurality of dots may be driven on the screen. One dot may correspond to one sub-pixel group, and the driving of one dot may be understood as the driving of one sub-pixel group.

As shown in FIG. 7, the display apparatus may include a first sub-pixel group PG1 corresponding to a first dot on the screen, a second sub-pixel group PG2 corresponding to a second dot on the screen, and a third sub-pixel group PG3 corresponding to a third dot on the screen. The display apparatus may further include a fourth sub-pixel group PG4 corresponding to a fourth dot on the screen. In addition, the display apparatus may further include an n^{th} sub-pixel group corresponding to an n^{th} dot on the screen.

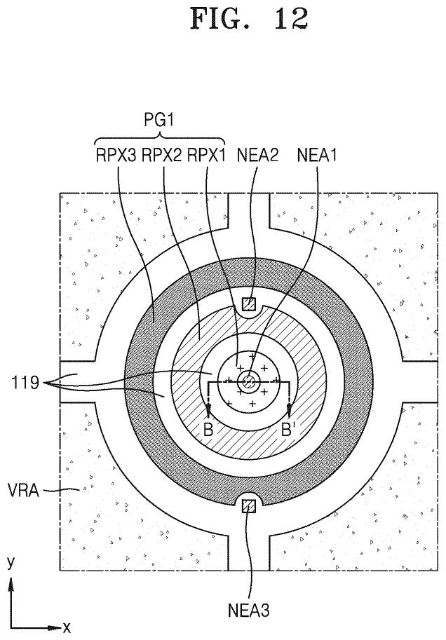

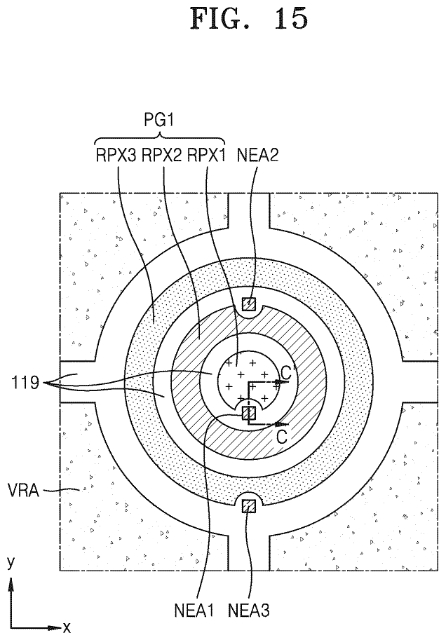

For example, when viewed in a plan view, the first sub-pixel RPX1 may have a circular shape or a ring shape. For convenience of illustration, the shape of the first sub-pixel RPX1 will be described in detail in the enlarged views of FIGS. 12 and 15.

For example, the first sub-pixel group PG1 may include the first sub-pixel RPX1, the second sub-pixel RPX2, and the third sub-pixel RPX3. The second sub-pixel RPX2 may have a ring shape surrounding the first sub-pixel RPX1. For example, the second sub-pixel RPX2 may be a ring type sub-pixel. The third sub-pixel RPX3 may have a ring shape surrounding the second sub-pixel RPX2. For example, the third sub-pixel RPX3 may be a ring type sub-pixel.

The second sub-pixel group PG2 may be spaced apart from the first sub-pixel group PG1 in the x-axis direction. The second sub-pixel group PG2 may include sub-pixels of the same type as the first sub-pixel group PG1.

The third sub-pixel group PG3 may be spaced apart from the first sub-pixel group PG1 in the-y-axis direction. The third sub-pixel group PG3 may include sub-pixels of the same type as the first sub-pixel group PG1.

The fourth sub-pixel group PG4 may be spaced apart from the third sub-pixel group PG3 in the x-axis direction and to be spaced apart from the second sub-pixel group PG2 in the-y-axis direction. The fourth sub-pixel group PG4 may include sub-pixels of the same type as the first sub-pixel group PG1.

The display apparatus may further include an additional component area VRA. For example, various components (for example, additional sub-pixels, additional sub-pixel groups, transmission portions, etc.) may be located in the additional component area VRA. The shape of the additional component area VRA is not necessarily limited to FIG. 7, and the shape of the additional component area VRA may be formed to correspond to the shape of the sub-pixel groups. The additional component area VRA may be surrounded by the first sub-pixel group PG1 to the fourth sub-pixel group PG4.

For example, when a transmission portion is located in the additional component area VRA, the sub-pixels in FIG. 7 may be the auxiliary sub-pixels mentioned above.

The pixel-defining layer may be observed between each of the sub-pixels. The pixel-defining layer may also be observed between sub-pixel groups or between a sub-pixel group and an additional component area.

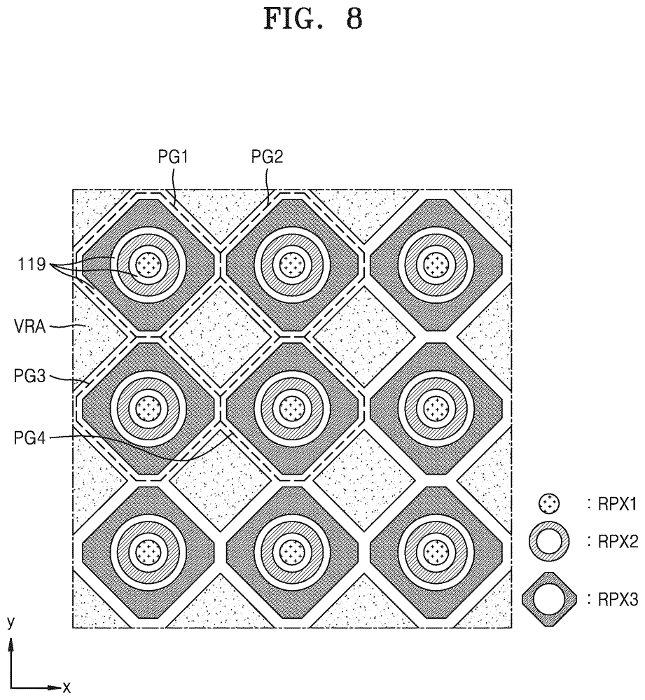

As shown in FIG. 8, the shape of the third sub-pixel RPX3 may be a rhombus shape with corners removed. The shape of the third sub-pixel RPX3 may be a rhombus shape with corners removed, but the inside of the third sub-pixel RPX3 may have a non-emission area with a shape corresponding to the shape of the second sub-pixel RPX2. The second sub-pixel RPX2 of a ring type may be located inside the third sub-pixel RPX3, and the first sub-pixel RPX1 may be located inside the second sub-pixel RPX2.

For example, the shape of the additional component area VRA may have a rhombus shape unlike the shape of the additional component area in FIG. 7. This is because the shape of the additional component area VRA corresponds to the shape of the sub-pixel groups, and the shape of the sub-pixel groups varies depending on the shape (e.g., the shape of the outer border) of the third sub-pixel RPX3 located at the outermost portion of the sub-pixel group.

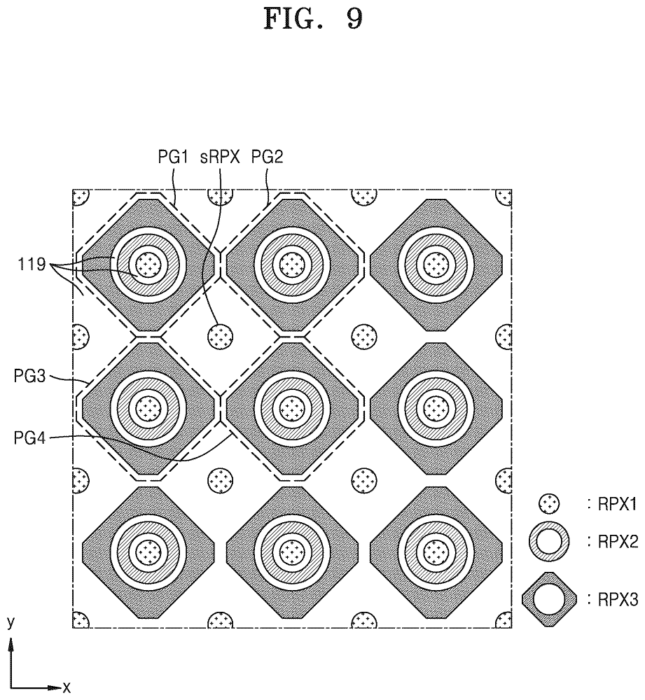

As shown in FIG. 9, an additional sub-pixel sRPX may be located between the sub-pixel groups. For example, the additional sub-pixel sRPX may be a sub-pixel of the same type as the first sub-pixel RPX1 mentioned above. For example, the additional sub-pixel sRPX may be a sub-pixel that generates visible light of the first wavelength band (for example, green visible light). Because the human eye is most sensitive to visible light of the first wavelength band, the resolution and brightness of the display apparatus may be increased through the additional sub-pixel sRPX that generates visible light of the first wavelength band. The additional sub-pixel sRPX may be surrounded by the first sub-pixel group PG1 to the fourth sub-pixel group PG4.

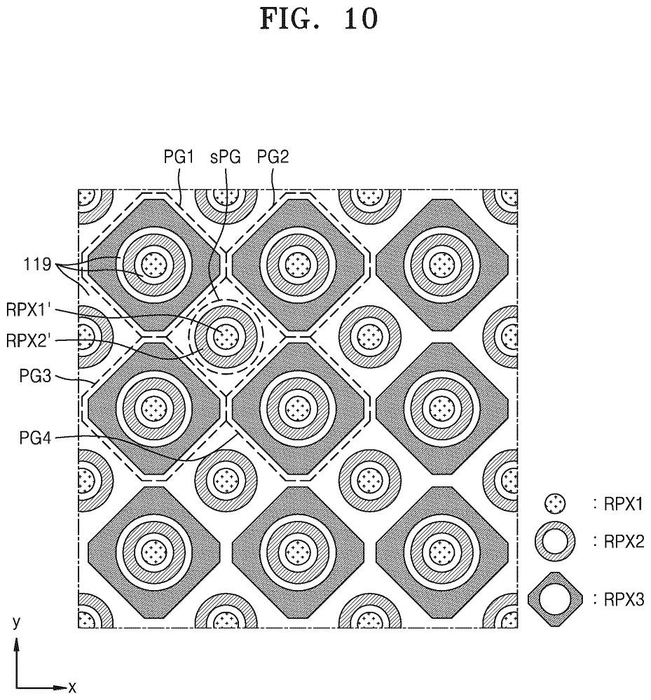

As shown in FIG. 10, an additional sub-pixel group sPG may be located between the sub-pixel groups. For example, the additional sub-pixel group sPG may include a first′ sub-pixel RPX1′ and a second′ sub-pixel RPX2′ of a ring type surrounding the first′ sub-pixel RPX1′. Because human eyes are not sensitive to visible light of the third wavelength band (for example, blue visible light), the third sub-pixel RPX3 may be omitted in the additional sub-pixel group sPG. In a plan view, the size of the first′ sub-pixel RPX1′ may be smaller than the size of the first sub-pixel RPX1, and the size of the second′ sub-pixel RPX2′ may be smaller than the size of the second sub-pixel RPX2. In this way, by additionally including the additional sub-pixel group sPG in a small space, the aspect of increasing the resolution and brightness of the display apparatus may be achieved. The additional sub-pixel group sPG may be surrounded by the first sub-pixel group PG1 to the fourth sub-pixel group PG4.

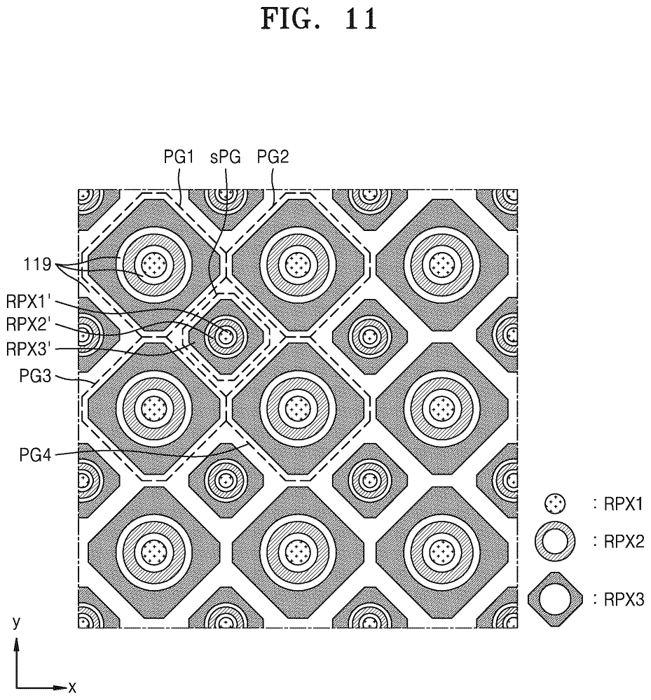

As shown in FIG. 11, the additional sub-pixel group sPG may be located between the sub-pixel groups. For example, the additional sub-pixel group sPG may include the first′ sub-pixel RPX1′, the second′ sub-pixel RPX2′ of a ring type surrounding the first′ sub-pixel RPX1′, and the third′ sub-pixel RPX3′ surrounding the second′ sub-pixel RPX2′ (e.g., surrounding in plan view). In a plan view, the size of the first′ sub-pixel RPX1′ may be smaller than the size of the first sub-pixel RPX1, the size of the second′ sub-pixel RPX2′ may be smaller than the size of the second sub-pixel RPX2, and the size of the third′ sub-pixel RPX3′ may be smaller than the size of the third sub-pixel RPX3. In this way, by additionally including the additional sub-pixel group sPG in a small space, the aspect of increasing the resolution and brightness of the display apparatus may be achieved. The additional sub-pixel group sPG may be surrounded by the first sub-pixel group PG1 to the fourth sub-pixel group PG4.

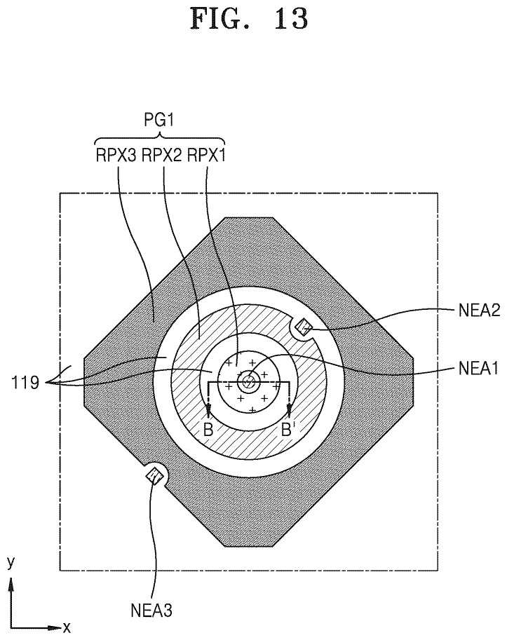

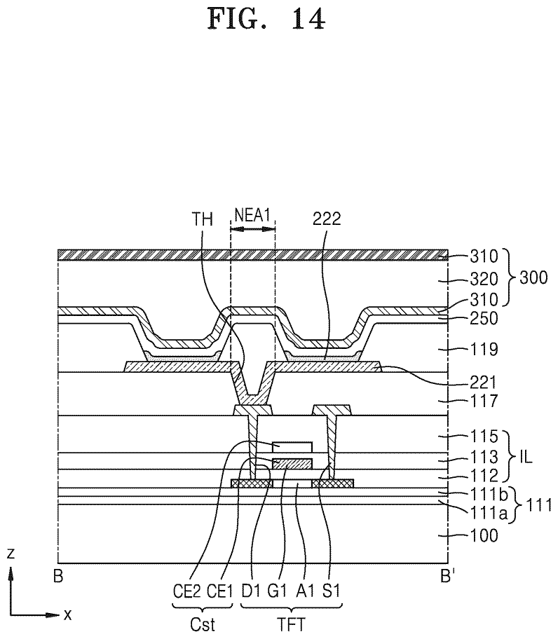

FIG. 12 is an enlarged view of the display panel, showing a first sub-pixel group of FIG. 7, according to one or more embodiments, FIG. 13 is an enlarged view of the display panel, showing a first sub-pixel group of FIGS. 8 to 11, according to one or more embodiments, and FIG. 14 is a cross-sectional view of the display panel taken along the line B-B′ of FIGS. 12 and 13, according to one or more embodiments.

For reference, descriptions of FIGS. 12 to 14 that are the same as or overlap with the above descriptions may be omitted for conciseness.

As shown in FIGS. 12 and 13, the first sub-pixel RPX1 may be a ring type sub-pixel. For example, the first sub-pixel RPX1 may be a ring type sub-pixel surrounding a first via hole area NEA1 (e.g., in plan view). For example, the first via hole area NEA1 may be located at the center of the first sub-pixel RPX1. The center of a sub-pixel may refer to the center of gravity of, or the geometric center of, the sub-pixel or the area around the center.

The first via hole area NEA1 may be a non-emission area. The first via hole area NEA1 may be an area corresponding to a first through hole formed in the planarization layer 117 as described below, which may refer to an area where the pixel-defining layer and the first through hole overlap when viewed in a direction perpendicular to the substrate (e.g., in a plan view).

A second via hole area NEA2 may be a non-emission area. The second via hole area NEA2 may be located around, or outside of, the outer border of the second sub-pixel RPX2 (e.g., in plan view). For example, the second sub-pixel RPX2 may have a shape that is indented toward the center by a second area in a plan view, and the second via hole area NEA2 may be located in the second area. As a result, the border of the second via hole area NEA2 and the outer border of the second sub-pixel RPX2 may be spaced apart.

The third via hole area NEA3 may be a non-emission area. The third via hole area NEA3 may be located around, or outside of, the outer border of the third sub-pixel RPX3 (e.g., in plan view). For example, the third sub-pixel RPX3 may have a shape that is indented toward the center by a third area in a plan view, and the third via hole area NEA3 may be located in the third area. As a result, the border of the third via hole area NEA3 and the outer border of the third sub-pixel RPX3 may be spaced apart.

For example, in a plan view, the first via hole area NEA1 may be located between the second via hole area NEA2 and the third via hole area NEA3. For example, the first via hole area NEA1 to the third via hole area NEA3 may be located on a straight line in a plan view.

By overlapping ring type sub-pixels, and by arranging the first via hole area NEA1 to the third via hole area NEA3 in a straight line, the process for forming the via hole areas may be simplified, improving manufacturing efficiency. Also, as the via hole areas are arranged in a straight line, the design of circuit wiring may be facilitated and signal interference may be reduced.

As shown in FIG. 14, the planarization layer 117 may have, or define, a first through hole TH. The first through hole TH may expose (e.g., upwardly expose) the upper surface of the first drain electrode D1 below the planarization layer. Through the first through hole TH, the first drain electrode D1 may be electrically connected to the pixel electrode.

The pixel electrode 221 may cover the inner surface of the first through hole TH and the upper surface of the first drain electrode D1. Accordingly, the pixel electrode 221 may have a step difference corresponding to the step difference of, or corresponding to, the first through hole TH. To planarize the step difference of the pixel electrode 221, the pixel-defining layer 119 may be located in the first via hole area NEA1. In a plan view, the first via hole area NEA1 may overlap with the first through hole TH.

In one or more embodiments, the second via hole area NEA2 may correspond to a second through hole formed in the planarization layer 117, may cover the inner surface of the second through hole, and may have a step difference corresponding to the step difference of the second through hole, in one or more embodiments. To planarize the step difference of the pixel electrode 221 corresponding to the step difference of the second through hole, the pixel-defining layer 119 may cover the step difference of the pixel electrode 221, in one or more embodiments.

In one or more embodiments, the third via hole area NEA3 may correspond to a third through hole formed in the planarization layer, may cover the inner surface of the third through hole, and may have a step difference corresponding to the step difference of the third through hole, in one or more embodiments. To planarize the step difference of the pixel electrode 221 corresponding to the step difference of the third through hole, the pixel-defining layer 119 may cover the step difference of the pixel electrode 221.

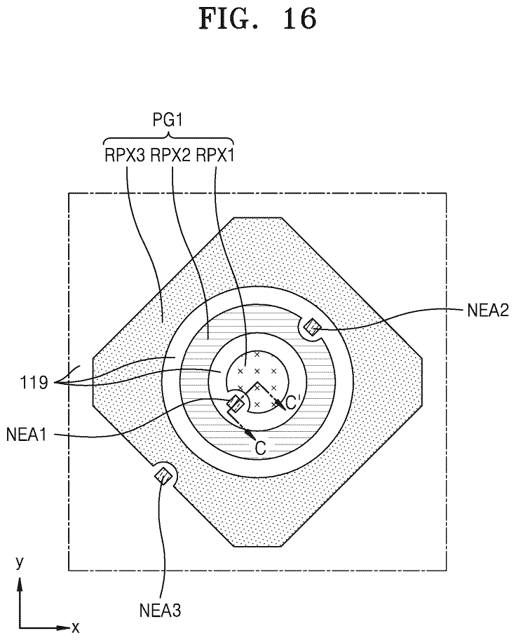

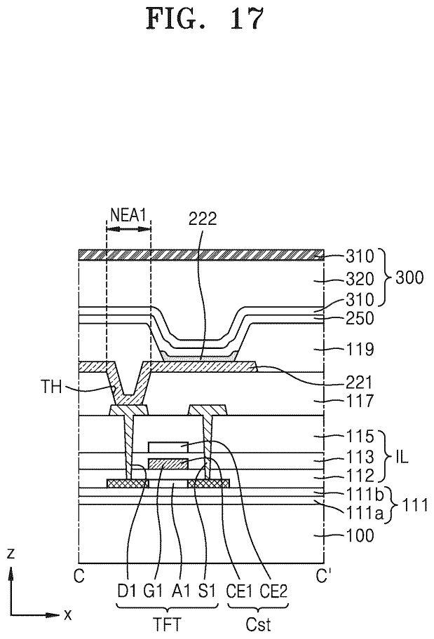

FIG. 15 is an enlarged view of the display panel, showing a first sub-pixel group of FIG. 7, according to one or more embodiments, FIG. 16 is an enlarged view of the display panel, showing a first sub-pixel group of FIGS. 8 to 11, according to one or more embodiments, and FIG. 17 is a cross-sectional view of the display panel taken along the line C-C′ of FIGS. 15 and 16, according to one or more embodiments.

For reference, descriptions of FIGS. 15 to 17 that are the same as or overlap with the above descriptions may be omitted for conciseness.

As shown in FIGS. 15 and 16, the first sub-pixel RPX1 may be a circular type sub-pixel. For example, the first via hole area NEA1 may be located around, or outside of, the outer border of the first sub-pixel RPX1. For example, the first sub-pixel RPX1 may have a shape that is indented toward the center by a first area in a plan view, and the first via hole area NEA1 may be located in the first area. As a result, the border of the first via hole area NEA1 and the outer border of the first sub-pixel RPX1 may be spaced apart.

For example, in a plan view, the first via hole area NEA1 may be located between the second via hole area NEA2 and the third via hole area NEA3. For example, the first via hole area NEA1 to the third via hole area NEA3 may be located on a straight line in a plan view. Similarly, the first area to the third area may be located on a straight line in a plan view.

As the size of the first sub-pixel RPX1 is secured, the emission efficiency is improved, and the aperture ratio is improved by arranging the second sub-pixel RPX2 and third sub-pixel RPX3 of a ring type to surround the first sub-pixel RPX1 (e.g., in plan view). Accordingly, the overall image quality of the display apparatus may be improved. In addition, high-resolution of the display apparatus can be achieved by enhancing pixel density through the overlapping layout of the sub-pixels.

As shown in FIG. 17, the planarization layer 117 may have the first through hole TH. The first through hole TH may upwardly expose the upper surface of the first drain electrode D1 below the planarization layer. Through the first through hole TH, the first drain electrode D1 may be electrically connected to the pixel electrode.

The pixel electrode 221 may cover the inner surface of the first through hole TH and the upper surface of the first drain electrode D1. Accordingly, the pixel electrode 221 may have a step difference corresponding to the step difference of the first through hole TH. To planarize the step difference of the pixel electrode 221, the pixel-defining layer 119 may be located in the first via hole area NEA1. In a plan view, the first via hole area NEA1 may overlap with the first through hole TH.

In one or more embodiments, the second via hole area NEA2 may correspond to a second through hole formed in the planarization layer 117, may cover the inner surface of the second through hole, and may have a step difference corresponding to the step difference of the second through hole, in one or more embodiments. To planarize the step difference of the pixel electrode 221 corresponding to the step difference of the second through hole, the pixel-defining layer 119 may cover the step difference of the pixel electrode 221.

In one or more embodiments, the third via hole area NEA3 may correspond to a third through hole formed in the planarization layer 117, may cover the inner surface of the third through hole, and may have a step difference corresponding to the step difference of the third through hole, in one or more embodiments. To planarize the step difference of the pixel electrode 221 corresponding to the step difference of the third through hole, the pixel-defining layer 119 may cover the step difference of the pixel electrode 221.

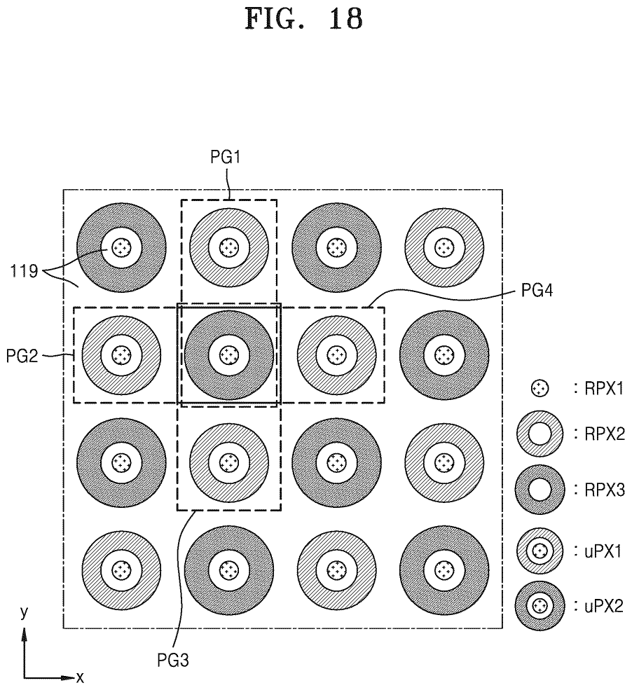

FIGS. 18 to 22 are plan views of the display panel, schematically showing a pixel pattern of a portion of a display area of FIG. 1, according to one or more embodiments. For reference, descriptions of FIGS. 18 to 22 that are the same as or overlap with the above descriptions of FIGS. 1 to 17 may be omitted for conciseness. The pixel patterns in FIGS. 18 to 22 may be patterns of sub-pixels in the first display area of FIG. 1.

As shown in FIG. 18, the display apparatus may include a plurality of sub-pixel groups. For example, the display apparatus may include the first sub-pixel group PG1 corresponding to the first dot on the screen, the second sub-pixel group PG2 corresponding to the second dot on the screen, the third sub-pixel group PG3 corresponding to the third dot on the screen, and the fourth sub-pixel group PG4 corresponding to the fourth dot on the screen. In addition, the display apparatus may include an n^{th} sub-pixel group corresponding to an n^{th} dot on the screen.

Each of the plurality of sub-pixel groups may include two sub-pixel units (e.g., two distinct types of sub-pixel units). For example, the first sub-pixel group PG1 may include a first sub-pixel unit uPX1 and a second sub-pixel unit uPX2. The first sub-pixel unit uPX1 may include the first sub-pixel RPX1 mentioned above, and the second sub-pixel RPX2 of a ring type surrounding the first sub-pixel RPX1 (e.g., in plan view). The second sub-pixel unit uPX2 may include the first sub-pixel RPX1, and the third sub-pixel RPX3 of a ring type surrounding the first sub-pixel RPX1 (e.g., in plan view). Because human eyes are least sensitive to the third wavelength band, the size of the third sub-pixel RPX3 may be larger than the size of the second sub-pixel RPX2.

The second sub-pixel unit uPX2 may be shared by the first sub-pixel group PG1 to the fourth sub-pixel group PG4. The second sub-pixel unit uPX2 shared by the first sub-pixel group PG1 to the fourth sub-pixel group PG4 may be called a common sub-pixel unit. In the disclosure, that sub-pixel groups share a sub-pixel or a sub-pixel unit may mean that the sub-pixel or the sub-pixel unit is involved in the driving of all the sub-pixel groups.

For example, the first sub-pixel group PG1 to the fourth sub-pixel group PG4 may radiate from the common sub-pixel unit as a center. For example, the first sub-pixel group PG1 and the third sub-pixel group PG3 may be located on a virtual straight line parallel to the y-axis direction, and the second sub-pixel group PG2 and the fourth sub-pixel group PG4 may be located on a virtual straight line parallel to the x-axis direction.

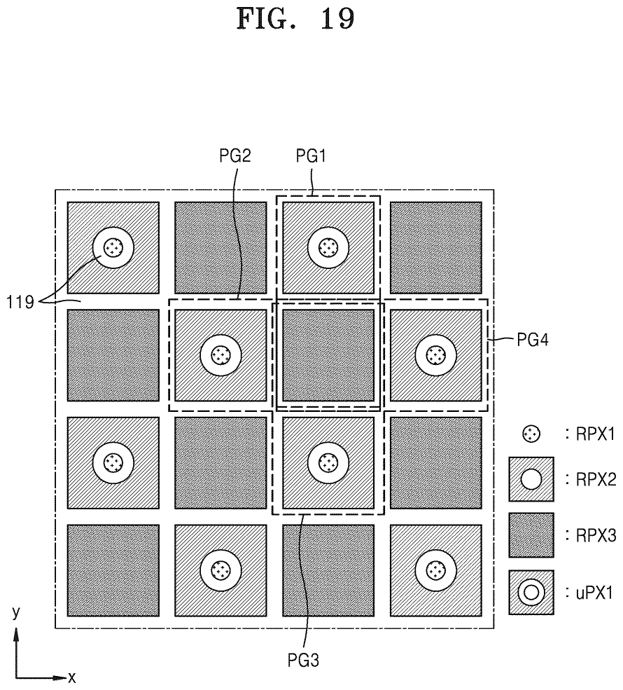

As shown in FIG. 19, each of the plurality of sub-pixel groups may include one sub-pixel and one sub-pixel unit. For example, the first sub-pixel group PG1 may include the first sub-pixel unit uPX1 and the third sub-pixel RPX3. The first sub-pixel unit uPX1 may include the first sub-pixel RPX1 mentioned above, and the second sub-pixel RPX2 surrounding the first sub-pixel RPX1 (e.g., in plan view). For example, the first sub-pixel RPX1 included in the first sub-pixel unit uPX1 may be a circular or ring type sub-pixel, and the second sub-pixel RPX2 included in the first sub-pixel unit uPX1 may be a rectangular or polygonal sub-pixel with a central area removed. The first sub-pixel RPX1 may be located in the area where the central area of the second sub-pixel RPX2 is removed, and the border of the first sub-pixel RPX1 may be spaced apart from the second sub-pixel RPX2.

The third sub-pixel RPX3 may be a rectangular or polygonal sub-pixel. Because human eyes are least sensitive to the third wavelength band, the size of the third sub-pixel RPX3 may be larger than the size of the second sub-pixel RPX2.

The third sub-pixel RPX3 may be shared by the first sub-pixel group PG1 to the fourth sub-pixel group PG4. The third sub-pixel RPX3 shared by the first sub-pixel group PG1 to the fourth sub-pixel group PG4 may be called a common sub-pixel. For example, the first sub-pixel group PG1 to the fourth sub-pixel group PG4 may radiate from the common sub-pixel as a center. For example, the first sub-pixel group PG1 and the third sub-pixel group PG3 may be located on a virtual straight line parallel to the y-axis direction, and the second sub-pixel group PG2 and the fourth sub-pixel group PG4 may be located on a virtual straight line parallel to the x-axis direction.

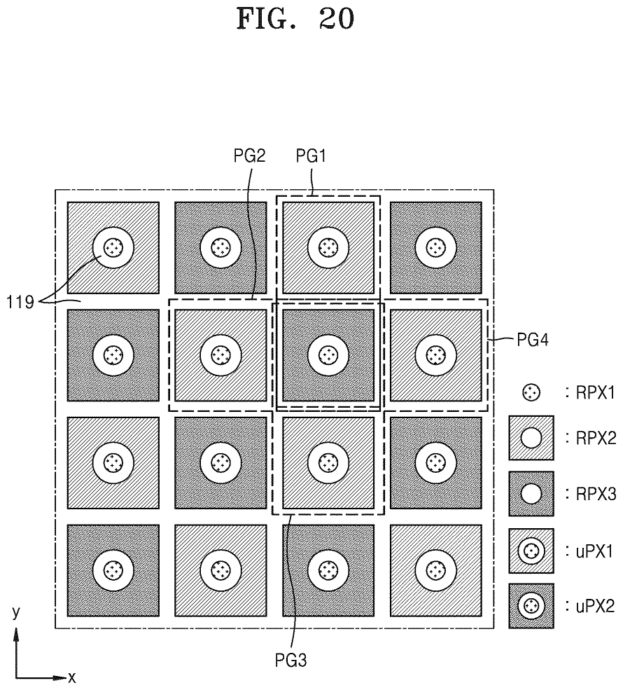

As shown in FIG. 20, each of the plurality of sub-pixel groups may include two sub-pixel units. For example, the first sub-pixel group PG1 may include the first sub-pixel unit uPX1 and the second sub-pixel unit uPX2. The first sub-pixel unit uPX1 may include the first sub-pixel RPX1 mentioned above and the second sub-pixel RPX2 surrounding the first sub-pixel RPX1. For example, the first sub-pixel RPX1 included in the first sub-pixel unit uPX1 may be a circular or ring type sub-pixel, and the second sub-pixel RPX2 included in the first sub-pixel unit uPX1 may be a rectangular or polygonal sub-pixel with a central area removed. The first sub-pixel RPX1 may be located in the area where the central area of the second sub-pixel RPX2 is removed, and the border of the first sub-pixel RPX1 may be spaced apart from the second sub-pixel RPX2.

For example, the second sub-pixel unit uPX2 may include the first sub-pixel RPX1 mentioned above, and the third sub-pixel RPX3 surrounding the first sub-pixel RPX1 (e.g., in plan view). For example, the first sub-pixel RPX1 included in the second sub-pixel unit uPX2 may be a circular or ring type sub-pixel, and the third sub-pixel RPX3 included in the second sub-pixel unit uPX2 may be a rectangular or polygonal sub-pixel with a central area removed. The first sub-pixel RPX1 may be located in the area where the central area of the third sub-pixel RPX3 is removed, and the border of the first sub-pixel RPX1 may be spaced apart from the third sub-pixel RPX3.

The second sub-pixel unit uPX2 may be shared by the first sub-pixel group PG1 to the fourth sub-pixel group PG4. The second sub-pixel unit uPX2 shared by the first sub-pixel group PG1 to the fourth sub-pixel group PG4 may be called a common sub-pixel unit. For example, the first sub-pixel group PG1 to the fourth sub-pixel group PG4 may radiate from the common sub-pixel unit as a center. For example, the first sub-pixel group PG1 and the third sub-pixel group PG3 may be located on a virtual straight line parallel to the y-axis direction, and the second sub-pixel group PG2 and the fourth sub-pixel group PG4 may be located on a virtual straight line parallel to the x-axis direction.

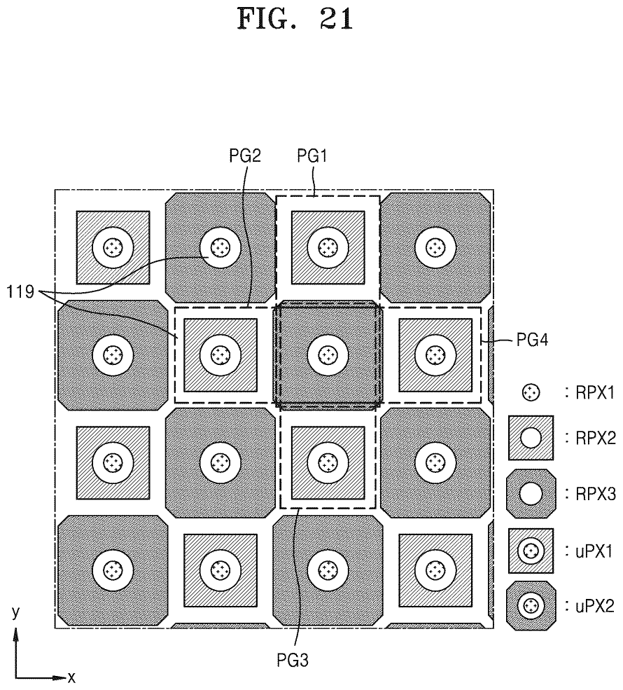

As shown in FIG. 21, the size of the second sub-pixel RPX2 of the first sub-pixel unit uPX1 may be smaller than the size of the third sub-pixel RPX3 of the second sub-pixel unit uPX2. To avoid interference with surrounding sub-pixels, the third sub-pixel RPX3 may have a rectangle or polygon shape with corners removed (or chamfered).

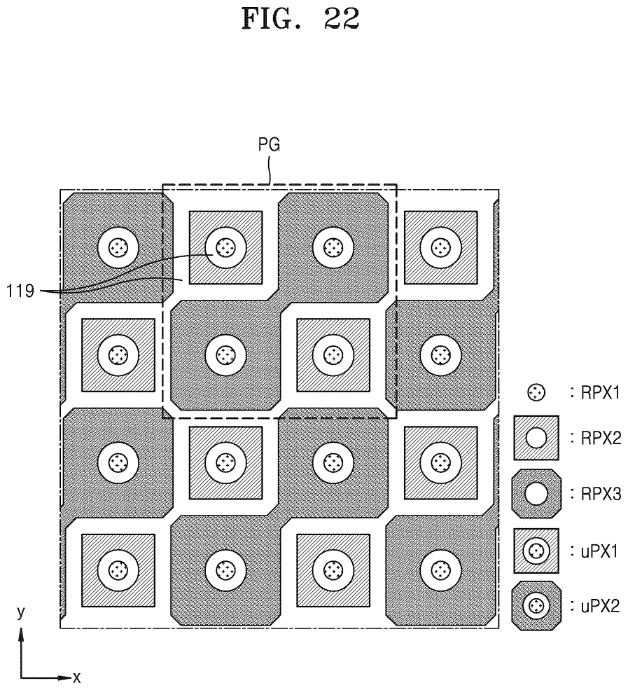

As shown in FIG. 22, each of the plurality of sub-pixel groups may include two first sub-pixel units uPX1 and two second sub-pixel units uPX2. For example, the two first sub-pixel units uPX1 may be arranged in a diagonal direction (for example, a direction between the-x-axis and the y-axis), and may be spaced apart from each other. For example, the two second sub-pixel units uPX2 may be arranged in a diagonal direction (for example, a direction between the x-axis and the y-axis), and the third sub-pixels RPX3 included in the second sub-pixel unit uPX2 may be connected to each other.

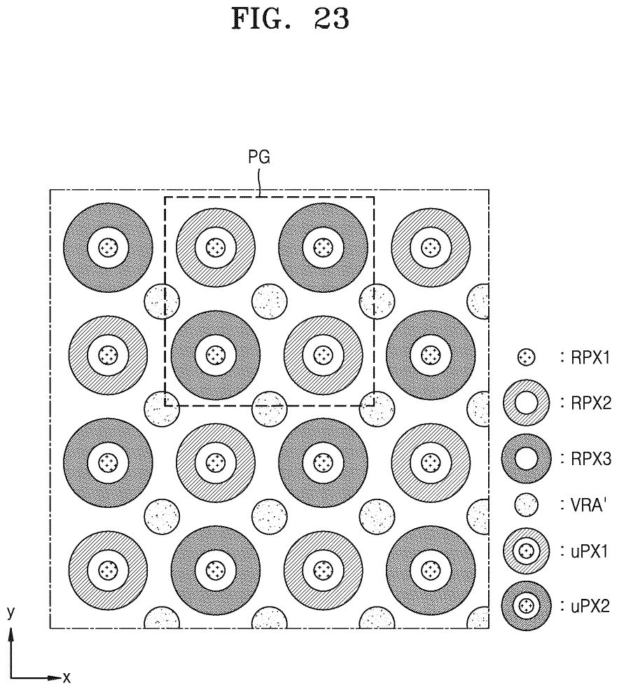

FIGS. 23 to 26 are plan views of the display panel, schematically showing a pixel pattern of a portion of a display area of FIG. 1, according to one or more embodiments. For reference, descriptions of FIGS. 23 to 26 that are the same as or overlap with the above descriptions of FIGS. 1 to 22 may be omitted for conciseness. The pixel patterns in FIGS. 23 to 26 may be patterns of sub-pixels in the first display area of FIG. 1.

As shown in FIG. 23, the display apparatus may further include an additional component VRA′. The additional component VRA′ may be located between the sub-pixel units. For example, the additional component VRA′ may be at least one of various sensors (for example, a bio sensor, an ultraviolet sensor, a camera light-receiving element, an organic solar cell, a White OLED, an additional sub-pixel, a via hole area, a transmission portion, etc.).

By utilizing sub-pixel units including circular or ring type sub-pixels as described, additional space may be formed in which the additional component VRA′ may be located. Various components may be located in the additional space. The additional component VRA′ may have a circular shape in a plan view.

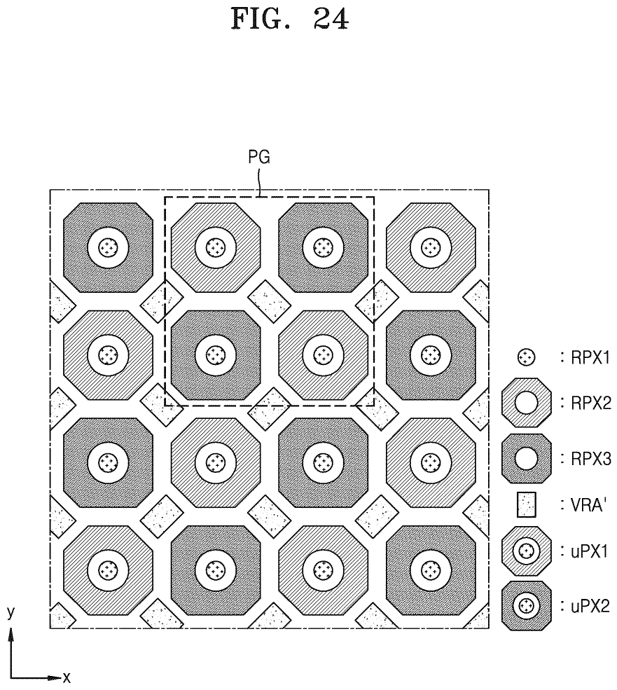

As shown in FIG. 24, when the shapes of the second sub-pixel RPX2 and the third sub-pixel RPX3 are rectangles or polygons with cut corners, the additional component VRA′ may have a rectangular shape, or parallelogram shape, in a plan view. The rectangle has a major axis and a minor axis, and the major axis may be oriented toward the first sub-pixel unit uPX1. For example, the major axis of the rectangle may be oriented toward the sub-pixel or the sub-pixel unit with more corners removed. For example, the second sub-pixel RPX2 may have a rectangular shape with corner areas removed by a first size, or by a first degree, and the third sub-pixel RPX3 may have a rectangular shape with corner areas removed by a second size, or by a second degree. When the first size is larger than the second size, the major axis of the rectangle of the additional component may be oriented toward the second sub-pixel RPX2 or the first sub-pixel unit uPX1 including the second sub-pixel RPX2.

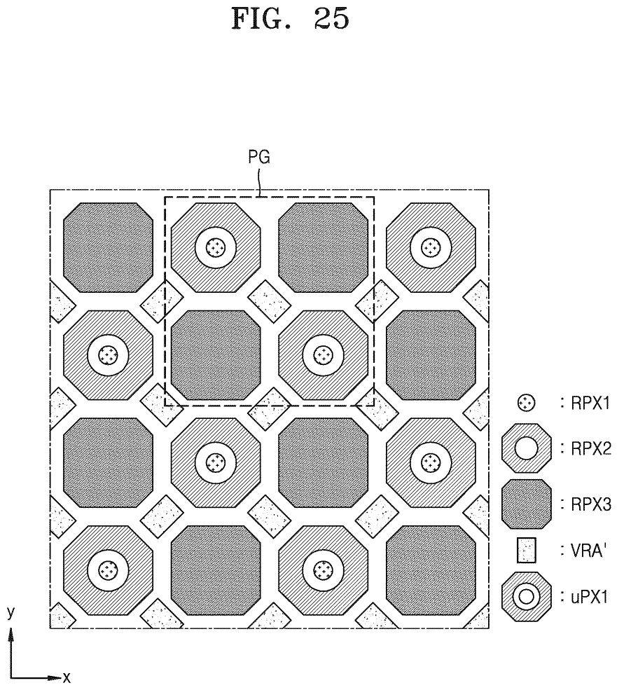

As shown in FIG. 25, even in the case where the third sub-pixel RPX3 is located instead of the second sub-pixel unit uPX2, when the shapes of the second sub-pixel RPX2 and the third sub-pixel RPX3 are rectangles or polygons with cut corners, the additional component VRA′ may have a rectangular or parallelogram shape in a plan view. The rectangle has a major axis and a minor axis, and the major axis may be oriented toward the first sub-pixel unit uPX1. For example, the major axis of the rectangle may be oriented toward the sub-pixel or the sub-pixel unit with more corners removed.

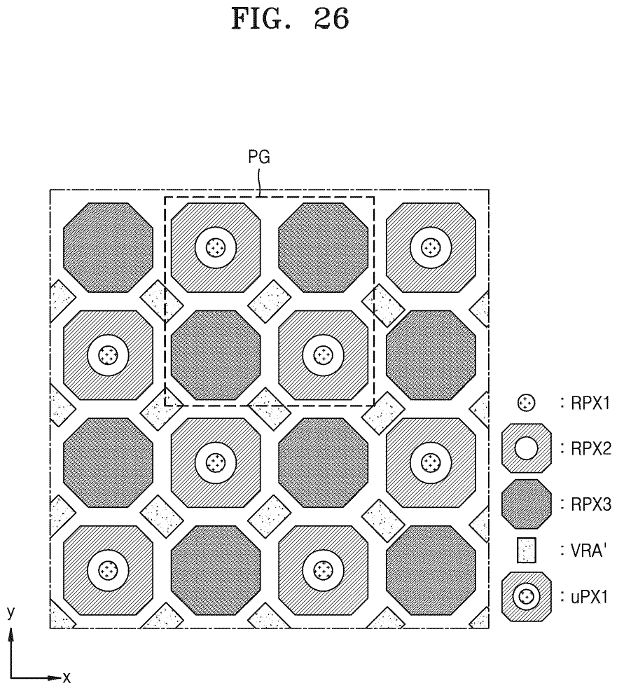

As shown in FIG. 26, for example, the second sub-pixel RPX2 may have a rectangular shape with corner areas removed by a first size, and the third sub-pixel RPX3 may have a rectangular shape with corner areas removed by a second size. When the second size is larger than the first size, the major axis of the rectangle of the additional component VRA′ may be oriented toward the third sub-pixel RPX3.

As shown in FIGS. 24 to 26, the arrangement of the additional component VRA′ may be made for improving or optimizing and making efficient use of space.

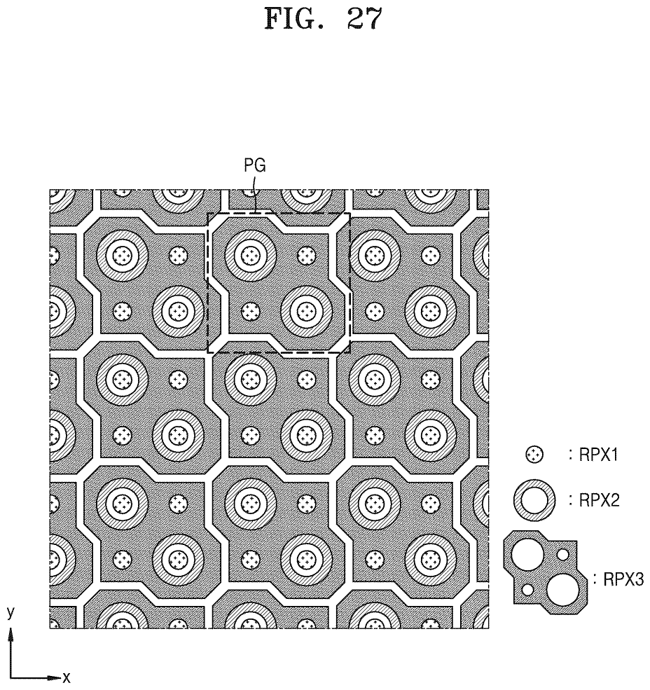

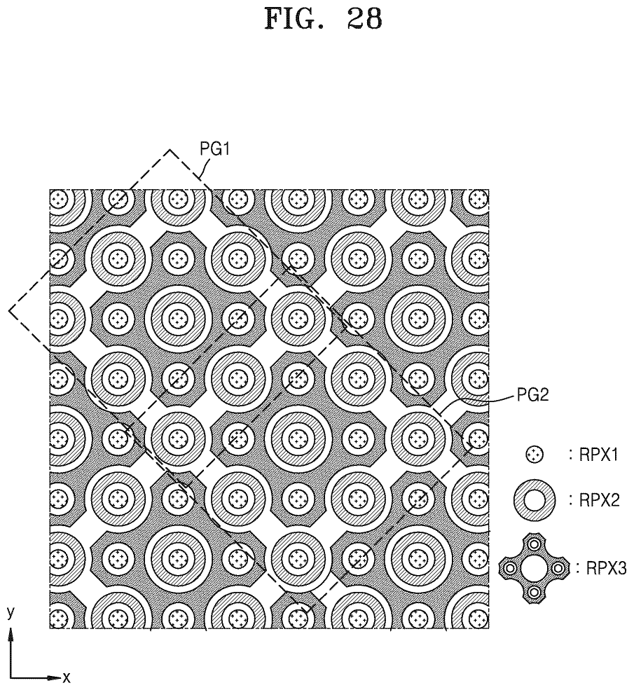

FIGS. 27 and 28 are plan views of the display panel, schematically showing a pixel pattern of a portion of a display area of FIG. 1, according to one or more embodiments. For reference, descriptions of FIGS. 27 to 28 that are the same as or overlap with the above descriptions of FIGS. 1 to 26 may be omitted for conciseness. The pixel patterns in FIGS. 27 and 28 may be patterns of sub-pixels in the first display area of FIG. 1.

As shown in FIG. 27, the sub-pixel group may include two first sub-pixels RPX1, two first sub-pixel units uPX1, and one third sub-pixel RPX3. The third sub-pixel RPX3 may surround the two first sub-pixels RPX1 and the two first sub-pixel units uPX1 (e.g., in plan view). For example, the first sub-pixel RPX1 and the first sub-pixel unit uPX1 may be located alternately on a straight line. The third sub-pixel RPX3 may have non-emission areas corresponding to the two first sub-pixels RPX1 and the two first sub-pixel units uPX1, and the two first sub-pixels RPX1 and the two first sub-pixel units uPX1 may be located in the non-emission areas within the third sub-pixel RPX3.

As shown in FIG. 28, the sub-pixel group may include four first sub-pixels RPX1, nine first sub-pixel units uPX1, and one third sub-pixel RPX3. The third sub-pixel RPX3 may surround the four first sub-pixels RPX1 and the nine first sub-pixel units uPX1 (e.g., in plan view).

For example, the first sub-pixel group PG1 and the second sub-pixel group PG2 may be adjacent to each other and may share three first sub-pixel units uPX1. The three first sub-pixel units uPX1 shared by the first sub-pixel group PG1 and the second sub-pixel group PG2 may be called common sub-pixel units.

For example, the first sub-pixel group PG1 may include one first sub-pixel unit uPX1 located at the center of the third sub-pixel RPX3 and four first sub-pixels RPX1 located around the one first sub-pixel unit uPX1 located at the center. The four first sub-pixels RPX1 may also be located within the third sub-pixel RPX3. The first sub-pixel group PG1 may further include eight first sub-pixel units uPX1 located around the four first sub-pixels RPX1. The eight first sub-pixel units uPX1 may surround the third sub-pixel RPX3 (e.g., in plan view).

For example, the first sub-pixel group PG1 may include one first sub-pixel unit uPX1 located at the center of the third sub-pixel RPX3, and a number n of first sub-pixels RPX1 located around the one first sub-pixel unit uPX1 located at the center (n being an integer). The number n of first sub-pixels RPX1 may also be located within the third sub-pixel RPX3. The first sub-pixel group PG1 may further include a number 2n of first sub-pixel units uPX1, which are located around the number n of first sub-pixels RPX1. A number of first sub-pixel units uPX1 included in the first sub-pixel group PG1 may be 2n+1, and some of the first sub-pixel units may be the common sub-pixel units. A number n of first sub-pixel units uPX1 may surround the third sub-pixel RPX3.

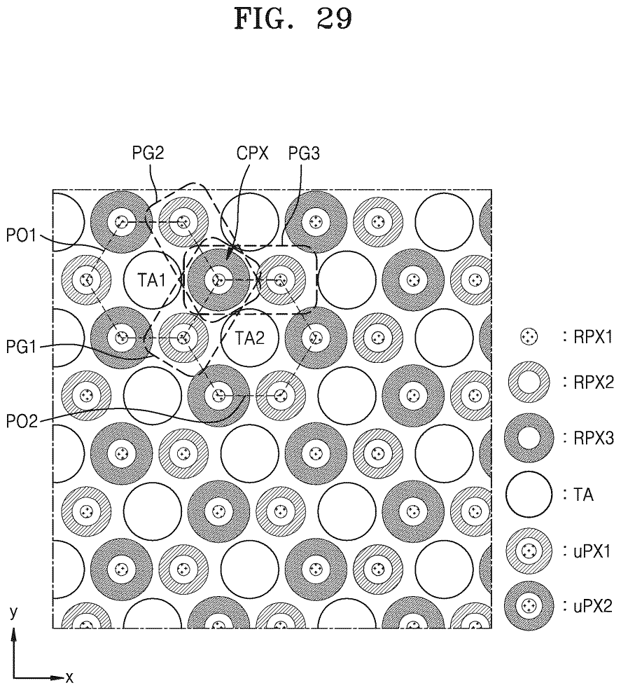

FIGS. 29 to 34 are plan views of the display panel, schematically showing a pixel pattern of a portion of a display area of FIG. 1, according to one or more embodiments. For reference, descriptions of FIGS. 29 to 34 that are the same as or overlap with the above descriptions of FIGS. 1 to 28 may be omitted for conciseness. The pixel patterns in FIGS. 29 to 34 may be patterns of auxiliary sub-pixels in the second display area of FIG. 1.

As shown in FIGS. 29 to 34, virtual polygons and sub-pixel groups may overlap in a plan view. Virtual line segments constituting the virtual polygon in a plan view may overlap with each other. For convenience of explanation, only some of the virtual polygons are shown in FIGS. 29 to 34, but it is understood that the auxiliary sub-pixel pattern may be interpreted based on the virtual polygons even in areas where the virtual polygons are not explicitly illustrated.

As shown in FIG. 29, a first virtual polygon PO1 may be adjacent to a second virtual polygon PO2. The first virtual polygon PO1 and the second virtual polygon PO2 may share a virtual line segment. The virtual polygons in FIG. 29 may be hexagons.

The display apparatus may include a plurality of sub-pixel units, and the plurality of sub-pixel units may overlap with the virtual polygons. For example, first sub-pixel units uPX1 and second sub-pixel units uPX2 may be alternately arranged to overlap with the virtual polygons. For example, each vertex of the first virtual polygon PO1 may overlap with the center of the first sub-pixel unit uPX1 or the center of the second sub-pixel unit uPX2. For example, each vertex of the second virtual polygon PO2 may overlap with the center of the first sub-pixel unit uPX1 or the center of the second sub-pixel unit uPX2.

The display apparatus may include a plurality of sub-pixel groups, and each of the plurality of sub-pixel groups may include at least two sub-pixel units. For example, the first sub-pixel group PG1 may include the first sub-pixel unit uPX1 and the second sub-pixel unit uPX2, and may share the second sub-pixel unit uPX2 with other sub-pixel groups. In the disclosure, a sub-pixel unit shared by sub-pixel groups may be called a common sub-pixel unit.

For example, the first sub-pixel group PG1 to the third sub-pixel group PG3 may share a common sub-pixel unit. The second sub-pixel group PG2 may include the first sub-pixel unit uPX1 and the common sub-pixel unit. The third sub-pixel group PG3 may include the first sub-pixel unit uPX1 and the common sub-pixel unit. For example, the first sub-pixel group PG1 to the third sub-pixel group PG3 may radiate from the common sub-pixel as a center.

A first transmission portion TA1 may be located within the first virtual polygon PO1. The first transmission portion TA1 may be surrounded by the plurality of sub-pixel groups. A second transmission portion TA2 may be located within the second virtual polygon PO2. The second transmission portion TA2 may be surrounded by the plurality of sub-pixel groups.

For example, when the first sub-pixel group PG1 is turned on, the common sub-pixel unit may emit light based on a first control command that controls the first sub-pixel group PG1. For example, when the first sub-pixel group PG1 and the second sub-pixel group PG2 are turned on, the common sub-pixel unit may emit light based on the first control command that controls the first sub-pixel group PG1 and a second control command that controls the second sub-pixel group PG2. For example, when the first sub-pixel group PG1 to the third sub-pixel group PG3 are turned on, the common sub-pixel may emit light based on the first control command that controls the first sub-pixel group PG1, the second control command that controls the second sub-pixel group PG2, and a third control command that controls the third sub-pixel group PG3.

For example, the control command may refer to the intensity of a driving current in the disclosure. Alternatively, the control command may refer to an electrical signal sent from a driving circuit to drive the sub-pixel group or the auxiliary sub-pixel included in the sub-pixel group.

For example, when one of the first sub-pixel group PG1, the second sub-pixel group PG2, or the third sub-pixel group PG3 is turned on, the common sub-pixel may emit light with a first brightness. Alternatively, when one of the first sub-pixel group PG1, the second pixel group PG2, or the third sub-pixel group PG3 is turned on, a driving current of a first magnitude may flow through the common sub-pixel.

For example, when two of the first sub-pixel group PG1 to the third sub-pixel group PG3 are turned on, the common sub-pixel unit may emit light with a second brightness that is brighter than the first brightness. Alternatively, when two of the first sub-pixel group PG1 to the third sub-pixel group PG3 are turned on, a driving current of a second magnitude that is larger than the first magnitude may flow through the common sub-pixel.

For example, when three of the first sub-pixel group PG1 to the third sub-pixel group PG3 are turned on, the common sub-pixel unit may emit light with a third brightness that is brighter than the second brightness. Alternatively, when three of the first sub-pixel group PG1, the second sub-pixel group PG2, or the third sub-pixel group PG3 are turned on, a driving current of a third magnitude that is larger than the second magnitude may flow.

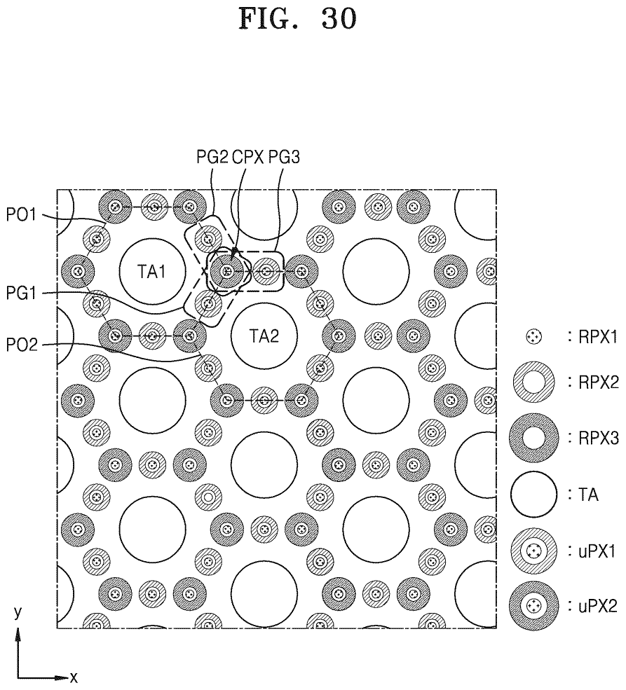

The correlation with respect to driving between the first sub-pixel group PG1 to the third sub-pixel group PG3 and the common sub-pixel unit as described above may be equally applied to one or more embodiments of FIG. 30 to be described below.

As shown in FIG. 30, the first virtual polygon PO1 may be adjacent to the second virtual polygon PO2. The first virtual polygon PO1 and the second virtual polygon PO2 may share a virtual line segment. The virtual polygons in FIG. 30 may be hexagons.

A first transmission portion TA1 may be located within the first virtual polygon PO1. The first transmission portion TA1 may be surrounded by the plurality of sub-pixel groups. A second transmission portion TA2 may be located within the second virtual polygon PO2. The second transmission portion TA2 may be surrounded by the plurality of sub-pixel groups.

Each of the virtual line segments constituting the virtual polygon and the plurality of sub-pixel units may overlap with each other. For example, at least three sub-pixel units may be located on one virtual line segment.

For example, the first sub-pixel group PG1 to the third sub-pixel group PG3 may share the common sub-pixel unit. The second sub-pixel group PG2 may include the first sub-pixel unit uPX1 and the common sub-pixel unit. The third sub-pixel group PG3 may include the first sub-pixel unit uPX1 and the common sub-pixel unit. For example, the first sub-pixel group PG1 to the third sub-pixel group PG3 may radiate from the common sub-pixel as a center.

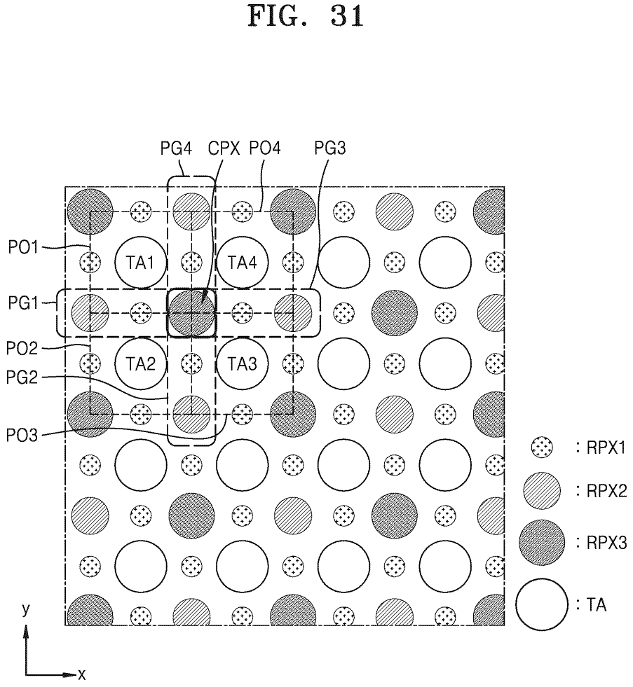

As shown in FIG. 31, the first virtual polygon PO1 may be adjacent to the second virtual polygon PO2. The second virtual polygon PO2 may be adjacent to a third virtual polygon PO3. The third virtual polygon PO3 may be adjacent to a fourth virtual polygon PO4.

The first transmission portion TA1 may be located within the first virtual polygon PO1. The second transmission portion TA2 may be located within the second virtual polygon PO2. A third transmission portion TA3 may be located within the third virtual polygon PO3. A fourth transmission portion TA4 may be located within the fourth virtual polygon PO4.

For example, the first sub-pixel group PG1 to the fourth sub-pixel group PG4 may share the common sub-pixel. Each of the sub-pixel groups may include the first sub-pixel RPX1 to the third sub-pixel RPX3, and the third sub-pixel RPX3 included in the first sub-pixel group PG1 to the fourth sub-pixel group PG4 may be the common sub-pixel. For example, the first sub-pixel group PG1 to the fourth sub-pixel group PG4 may radiate from the common sub-pixel as a center. For example, the shapes of the first sub-pixel RPX1 to the third sub-pixel RPX3 may be circular.

For example, when the first sub-pixel group PG1 is turned on, the common sub-pixel may emit light based on the first control command that controls the first sub-pixel group PG1. For example, when the first sub-pixel group PG1 and the second sub-pixel group PG2 are turned on, the common sub-pixel may emit light based on the first control command that controls the first sub-pixel group PG1, and based on the second control command that controls the second sub-pixel group PG2. For example, when the first sub-pixel group PG1 to the third sub-pixel group PG3 are turned on, the common sub-pixel may emit light based on the first control command that controls the first sub-pixel group PG1, based on the second control command that controls the second sub-pixel group PG2, and based on the third control command that controls the third sub-pixel group PG3. For example, when the first sub-pixel group PG1 to the fourth sub-pixel group PG4 are turned on, the common sub-pixel may emit light based on the first control command that controls the first sub-pixel group PG1, the second control command that controls the second sub-pixel group PG2, the third control command that controls the third sub-pixel group PG3, and a fourth control command that controls the fourth sub-pixel group PG4.

For example, when one of the first sub-pixel group PG1 to the fourth sub-pixel group PG4 is turned on, the common sub-pixel may emit light with the first brightness. Alternatively, when one of the first sub-pixel group PG1 to the fourth sub-pixel group PG4 is turned on, the driving current of the first magnitude may flow through the common sub-pixel.

For example, when two of the first sub-pixel group PG1 to the fourth sub-pixel group PG4 are turned on, the common sub-pixel may emit light with the second brightness that is brighter than the first brightness. Alternatively, when two of the first sub-pixel group PG1 to the fourth sub-pixel group PG4 are turned on, the driving current of the second magnitude that is larger than the first magnitude may flow through the common sub-pixel. For example, the second magnitude may be twice the first magnitude.

For example, when three of the first sub-pixel group PG1 to the fourth sub-pixel group PG4 are turned on, the common sub-pixel may emit light with the third brightness that is brighter than the second brightness. Alternatively, when three of the first sub-pixel group PG1 to the fourth sub-pixel group PG4 are turned on, the driving current of the third magnitude that is larger than the second magnitude may flow through the common sub-pixel.

For example, when four of the first sub-pixel group PG1 to the fourth sub-pixel group PG4 are turned on, the common sub-pixel may emit light with a fourth brightness that is brighter than the third brightness. Alternatively, when four of the first sub-pixel group PG1 to the fourth sub-pixel group PG4 are turned on, a driving current of a fourth magnitude that is larger than the third magnitude may flow through the common sub-pixel.

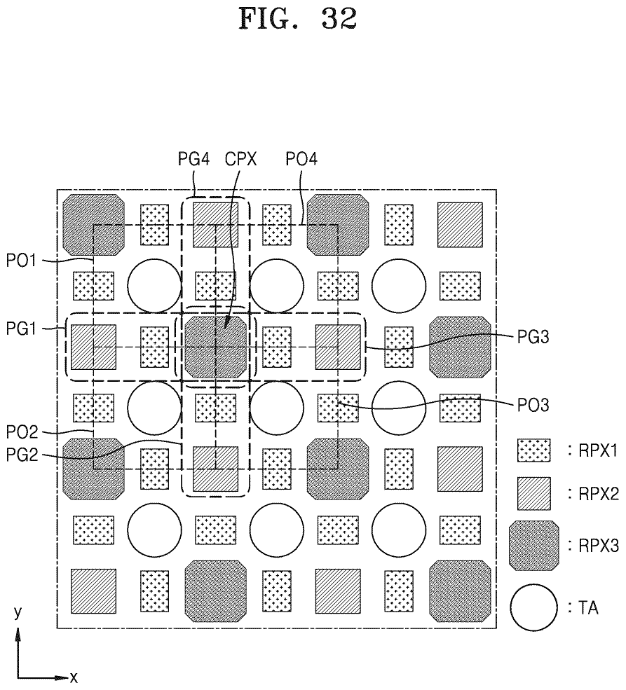

The correlation between the first sub-pixel group PG1 to the fourth sub-pixel group PG4 and the common sub-pixel regarding driving as described above may be equally applied to one or more embodiments of FIGS. 32 to 35 to be described below.

As shown in FIG. 32, the shapes of the first sub-pixel RPX1 to the third sub-pixel RPX3 may be polygonal. For example, the shape of each of the first sub-pixel RPX1 and the second sub-pixel RPX2 may be rectangular in a plan view. The shape of the third sub-pixel RPX3 may be a rectangle with corners removed (or chamfered).

For example, the shape of the first sub-pixel RPX1 may be a rectangle. For example, the major axis of the rectangle may be oriented toward the transmission portion TA located within the virtual polygon, and the minor axis of the rectangle may be oriented toward the second sub-pixel RPX2 and the third sub-pixel RPX3.

The first sub-pixel RPX1 may have a shape in which the major axis of the rectangle is oriented toward the transmission portion TA, so that the emission brightness around the transmission portion TA may be enhanced. Accordingly, a substantially uniform brightness distribution may be implemented to compensate for the degradation of image quality caused by the transmission portion TA. Additionally, the minor axis of the rectangle may be oriented toward the second sub-pixel RPX2 and the third sub-pixel RPX3, so that the interference between sub-pixels may be reduced or prevented while enabling efficient utilization of space.

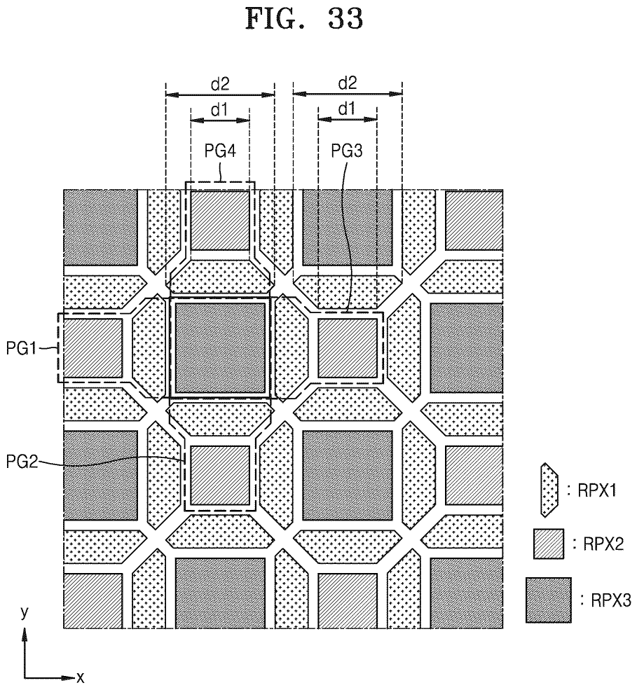

As shown in FIG. 33, the shape of each of the second sub-pixel RPX2 and the third sub-pixel RPX3 may be a rectangle or square with different sizes. The shape of the first sub-pixel RPX1 may be a trapezoid corresponding to both the shape of the second sub-pixel RPX2 and the shape of the third sub-pixel RPX3. For example, the trapezoidal shape of the first sub-pixel RPX1 may include a long side and a short side that are parallel. The long side of the trapezoidal shape of the first sub-pixel RPX1 may be located around the third sub-pixel RPX3, and the short side of the trapezoidal shape of the first sub-pixel RPX1 may be located around the second sub-pixel RPX2. For example, the long side of the trapezoidal shape of the first sub-pixel RPX1 may be located parallel to one side of the third sub-pixel RPX3 around one side of the third sub-pixel RPX3. For example, the short side of the trapezoidal shape of the first sub-pixel RPX1 may be located parallel to one side of the second sub-pixel RPX2 around one side of the second sub-pixel RPX2.

For example, the trapezoidal shape of the first sub-pixel RPX1 may be a trapezoid with both corners of the long side removed (chamfered). This shape is provided to reduce or prevent interference with other first sub-pixels RPX1.

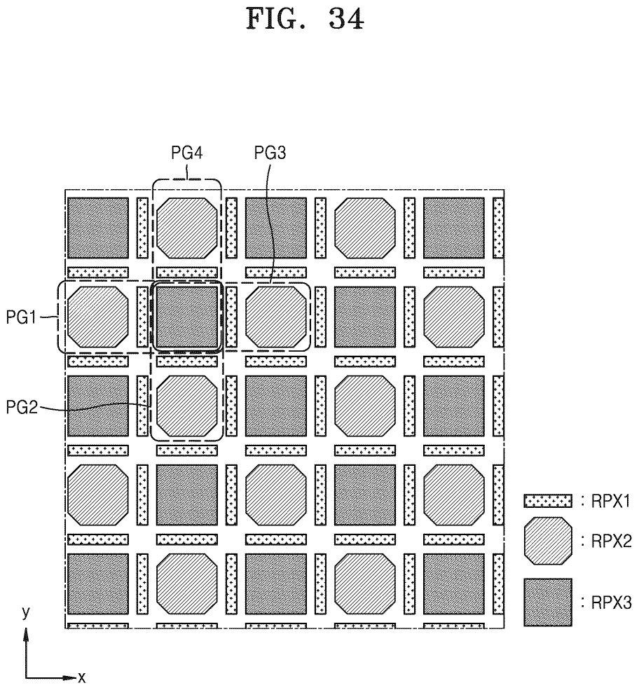

As shown in FIG. 34, the shape of the third sub-pixel RPX3 may be rectangular, and the shape of the second sub-pixel RPX2 may be a rectangle with four corners removed (or chamfered). As a result, the size of the second sub-pixel RPX2 may be smaller than the size of the third sub-pixel RPX3. The shape of the first sub-pixel RPX1 may be an elongated rectangle. The first sub-pixel RPX1 may be located between the second sub-pixel RPX2 and the third sub-pixel RPX3, and the rectangular shape of the first sub-pixel RPX1 may include a long side, and a short side perpendicular to the long side. The short side of the first sub-pixel RPX1 may be oriented toward the second sub-pixel RPX2 and the third sub-pixel RPX3, and the long side of the first sub-pixel RPX1 may be located around the second sub-pixel RPX2 and the third sub-pixel RPX3. The short side of the first sub-pixel RPX1 may be located parallel to the x-axis direction, and the long side of the first sub-pixel RPX1 may be located parallel to the y-axis direction.

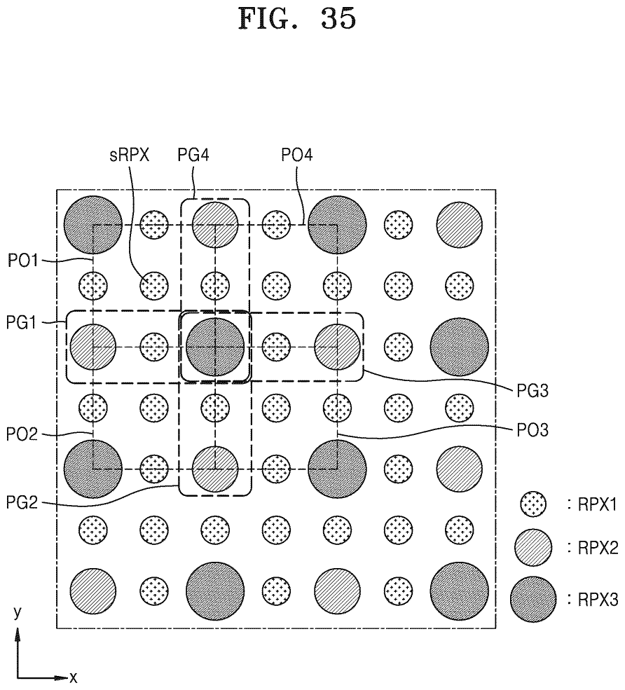

FIGS. 35 to 38 are plan views of the display panel, schematically showing a pixel pattern of a portion of a display area of FIG. 1, according to one or more embodiments. For reference, descriptions of FIGS. 35 to 38 that are the same as or overlap with the above descriptions of FIGS. 1 to 34 may be omitted for conciseness. The pixel patterns in FIGS. 35 to 38 may be patterns of auxiliary sub-pixels in the second display area of FIG. 1.

As shown in FIG. 35, the first virtual polygon PO1 may be adjacent to the second virtual polygon PO2. The second virtual polygon PO2 may be adjacent to the third virtual polygon PO3. The third virtual polygon PO3 may be adjacent to the fourth virtual polygon PO4. For example, an additional sub-pixel sRPX may be located within each of the virtual polygons. The additional sub-pixel sRPX may be a sub-pixel of the same type as the first sub-pixel RPX1.

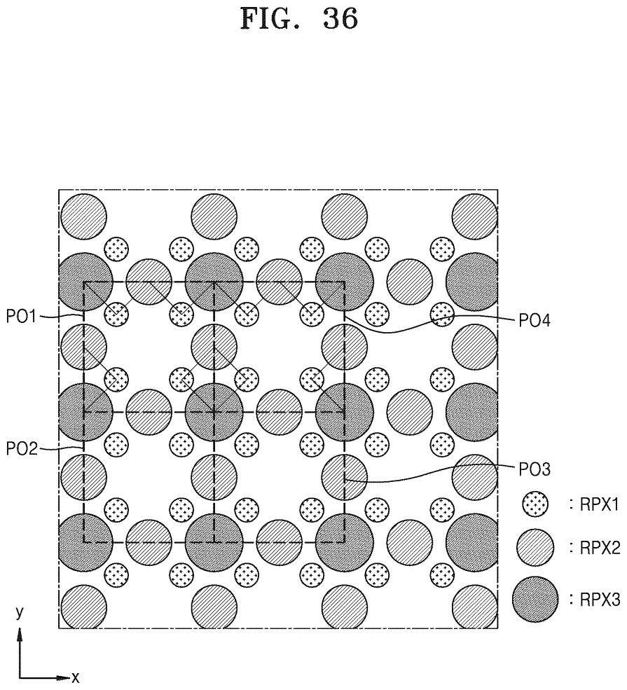

As shown in FIGS. 36 to 38, the third sub-pixel RPX3 may be located at each corner of the virtual polygons. The second sub-pixel RPX2 may be located between the corners of the virtual polygons, and may be located at the center of the virtual line segment constituting the virtual polygon.

The first sub-pixel RPX1 may be located around the second sub-pixel RPX2 and the third sub-pixel RPX3. The first sub-pixel RPX1 may be located within the virtual polygon. A plurality of first sub-pixels RPX1 may be located within the virtual polygon. For example, four first sub-pixels RPX1 may be located within the virtual polygon. For example, the shape of the first sub-pixel RPX1 may be circular or elliptical.

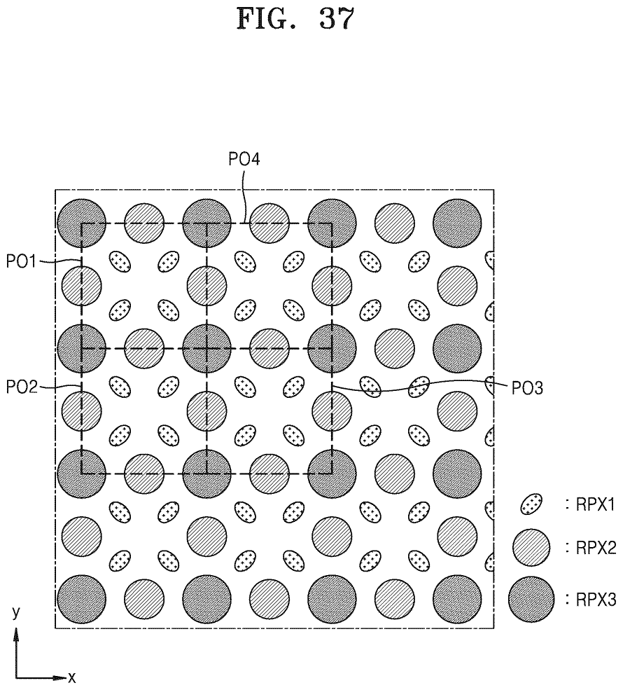

As shown in FIG. 37, when the shape of the first sub-pixel RPX1 is elliptical, the ellipse may have a major axis and a minor axis. For example, one end of the major axis of the ellipse may be oriented toward the third sub-pixel RPX3 around the ellipse. For example, the other end of the major axis of the ellipse may be oriented toward the center of the virtual polygon.

The major axis of the sub-pixel having an elliptical shape is located in the direction connecting the third sub-pixel and the center of the polygon, the emission area may be increased while improving or optimizing the spacing between sub-pixels. Additionally, pixel density may be increased and aperture ratio may be improved, while reducing or preventing electrical interference between sub-pixels.

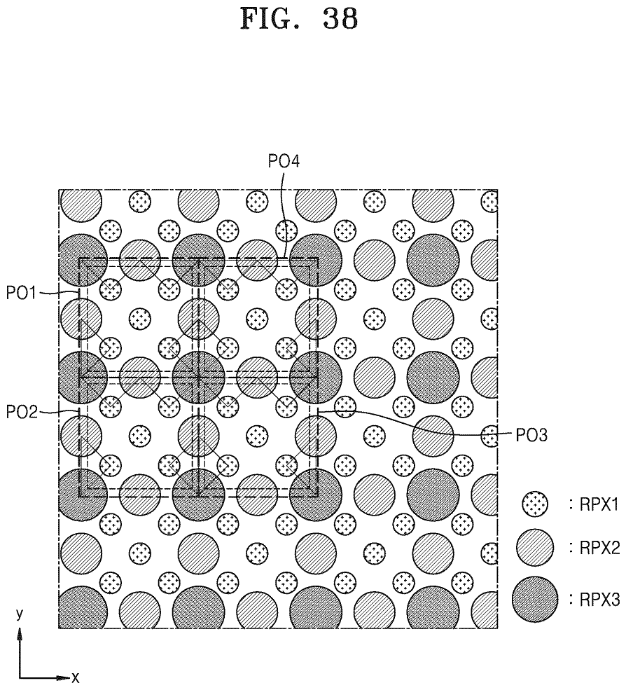

As shown in FIG. 38, the additional sub-pixel sRPX may be located at the center of the virtual polygon. The additional sub-pixel sRPX may be a sub-pixel of the same type as the first sub-pixel RPX1.

Hereinafter, an electronic device according to one or more embodiments will be described in detail based on the above descriptions.

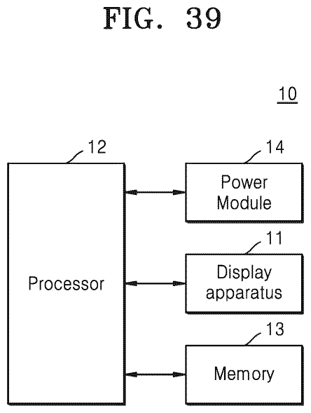

FIG. 39 is a block diagram of an electronic device 10 according to one or more embodiments.

Referring to FIG. 39, the electronic device 10 according to one or more embodiments may include a display apparatus 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information needed for the operation of the processor 12 or the display apparatus 11. When the processor 12 executes an application stored in the memory 13, video data signals and/or input control signals are delivered to the display apparatus 11, and the display apparatus 11 may process the provided signals to output video information through the display screen.

The power module 14 may include a power supply module, such as a power adapter or a battery device, and a power conversion module that converts power supplied by the power supply module to generate power needed for the operation of the electronic device 10.

At least one of the elements of the electronic device 10 described above may be included in the display apparatus 11 according to the embodiments described above. Also, some of the individual modules included in a functionally integrated module may be provided within the display apparatus 11, while others may be provided separately from the display apparatus 11. For example, the processor 12, the memory 13, and the power module 14 may be provided in the form of other devices in the electronic device 10 that are not the display apparatus 11.

The display apparatus 11 in FIG. 39 may refer to one of the embodiments of the display apparatus 11 described in FIGS. 1 to 38. For convenience of explanation, additional explanations are omitted, but one of ordinary skill in the art may easily and clearly understand the display apparatus 11 of FIG. 39 from the descriptions of FIGS. 1 to 38.

In one or more embodiments, the electronic device 10 may include the memory 13 storing data information, the processor 12 for generating data signals and/or control signals based on the data information, and the display apparatus 11 operating based on the data signals and/or control signals. The display apparatus 11 may be any one of the display apparatus 11 of FIGS. 1 to 38.

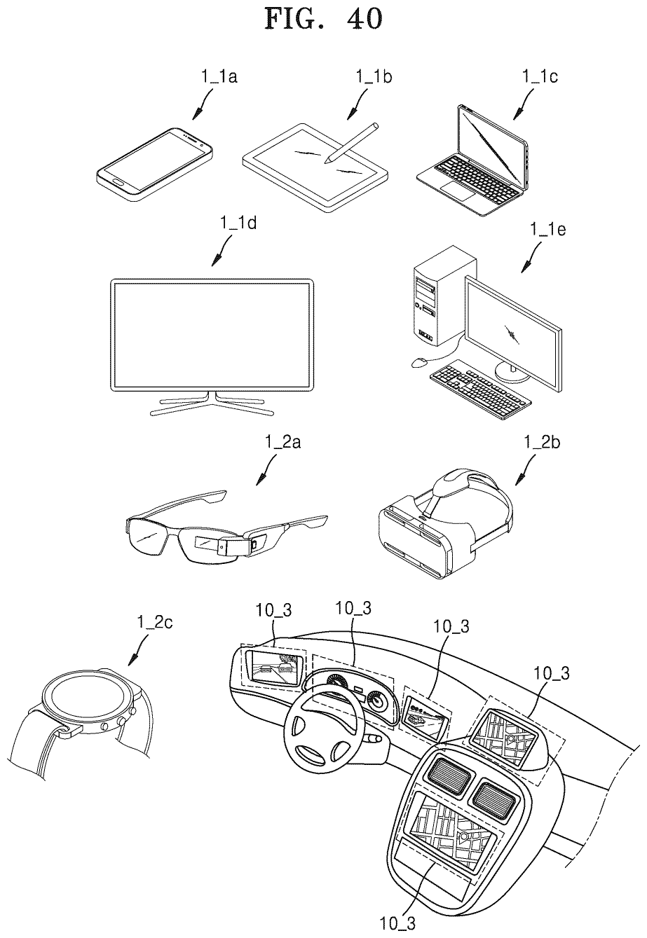

FIG. 40 is a schematic diagram of electronic devices according to various embodiments.

Referring to FIG. 40, various electronic devices to which the display apparatus 11 according to embodiments is applied may include image display electronic devices, such as smartphones 1_1a, tablet PCs 1_1b, laptops 1_1c, TVs 1_1d, desktop monitors 1_1e, as well as wearable electronic devices including display apparatuses, such as smart glasses 10_2a, head mounted displays 1_2b, and smart watches 1_2c, and vehicle electronic devices 10_3 including display apparatuses, such as automobile instrument panels, center fascias, Center Information Displays (CID) located on dashboards, room mirror displays, etc.

According to embodiments as described above, a display apparatus having an efficient pixel structure and an electronic device including the display apparatus can be implemented. It is understood that the scope of the disclosure is not necessarily limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a first sub-pixel group corresponding to a first dot on a screen, and comprising:
a first via hole area;
a ring type first sub-pixel surrounding the first via hole area in a plan view;
a ring type second sub-pixel surrounding the first sub-pixel in a plan view; and
a ring type third sub-pixel surrounding the second sub-pixel in a plan view;
a second sub-pixel group corresponding to a second dot on the screen; and
a third sub-pixel group corresponding to a third dot on the screen.

2. The display apparatus of claim 1, wherein the first sub-pixel group further comprises:
a second via hole area outside an outer border of the second sub-pixel; and
a third via hole area outside an outer border of the third sub-pixel.

3. The display apparatus of claim 2, wherein the second sub-pixel has a shape that is indented toward a center by a second area in a plan view,
wherein the second via hole area is in the second area,
wherein the third sub-pixel has a shape that is indented toward the center by a third area in a plan view, and
wherein the third via hole area is in the third area.

4. The display apparatus of claim 1, wherein a geometric center of the second sub-pixel and a geometric center of the third sub-pixel are within the first sub-pixel in a plan view.

5. The display apparatus of claim 2, wherein the first via hole area, the second via hole area, and the third via hole area overlap a virtual straight line.

6. The display apparatus of claim 1, wherein a cross section of the first via hole area comprises:
a substrate;
a thin film transistor layer above the substrate and comprising a thin film transistor;
a first insulating layer above the thin film transistor layer;
a conductive layer above the first insulating layer;
a second insulating layer above the conductive layer and defining a through hole exposing an upper surface of the conductive layer;
a pixel electrode above the second insulating layer and electrically connected to the conductive layer through the through hole; and
a pixel-defining layer above the pixel electrode.

7. The display apparatus of claim 6, wherein, in a plan view, the through hole is at a center of the first sub-pixel, and
wherein the pixel electrode has a step difference at the through hole.

8. The display apparatus of claim 7, wherein the pixel-defining layer covers the step difference.

9. The display apparatus of claim 2, wherein the first via hole area, the second via hole area, and the third via hole area are non-emission areas.

10. The display apparatus of claim 1, further comprising an additional component area surrounded by the first sub-pixel group, the second sub-pixel group, and the third sub-pixel group in a plan view.

11. The display apparatus of claim 10, further comprising an additional sub-pixel in the additional component area.

12. The display apparatus of claim 10, further comprising an additional sub-pixel group in the additional component area.

13. A display apparatus comprising:
a first sub-pixel group corresponding to a first dot on a screen and comprising:
a first sub-pixel;
a ring type second sub-pixel surrounding the first sub-pixel in a plan view;
a ring type third sub-pixel surrounding the second sub-pixel in a plan view; and
a first via hole area outside an outer border of the first sub-pixel;
a second sub-pixel group corresponding to a second dot on the screen; and
a third sub-pixel group corresponding to a third dot on the screen.

14. The display apparatus of claim 13, wherein the first sub-pixel group further comprises:
a second via hole area outside an outer border of the second sub-pixel; and
a third via hole area outside an outer border of the third sub-pixel.

15. The display apparatus of claim 14, wherein the first sub-pixel has a shape that is indented toward a center by a first area in a plan view, and
wherein the first via hole area is in the first area.

16. The display apparatus of claim 15, wherein the second sub-pixel has a shape that is indented toward the center by a second area in a plan view,
wherein the second via hole area is in the second area, and
wherein the third sub-pixel has a shape that is indented toward the center by a third area in a plan view, and
wherein the third via hole area is in the third area.

17. The display apparatus of claim 14, wherein, in a plan view, the first via hole, the second via hole area, and the third via hole area overlap a virtual straight line.

18. The display apparatus of claim 14, wherein, in a plan view, the first via hole area is at a first side of the first sub-pixel, and
wherein, in a plan view, the second via hole area is at a second side of the second sub-pixel that is opposite to the first side such that a center of the first sub-pixel is between the first via hole area and the second via hole area.

19. The display apparatus of claim 18, wherein, in a plan view, the third via hole area is at a first side of the third sub-pixel.

20. An electronic device comprising:
a memory for storing data information;
a processor configured to generate a data signal and/or a control signal based on the data information; and
a display apparatus configured to receive the data signal and/or the control signal, and comprising:
a first sub-pixel group corresponding to a first dot on a screen, and comprising:
a first via hole area;
a ring type first sub-pixel surrounding the first via hole area in a plan view;
a ring type second sub-pixel surrounding the first sub-pixel in a plan view; and
a ring type third sub-pixel surrounding the second sub-pixel in a plan view;
a second sub-pixel group corresponding to a second dot on the screen; and
a third sub-pixel group corresponding to a third dot on the screen.
